(19) United States
(12) Patent Application Publication
(10) Pub. No.: US 2023/0253349 A1
(43) Pub. Date: Aug. 10, 2023

(54) SEMICONDUCTOR DEVICE, MANUFACTURING METHOD THEREOF AND POWER CONVERTER

(71) Applicant: Mitsubishi Electric Corporation, Tokyo (JP)

(72) Inventor: Yuji SATO, Tokyo (JP)

(73) Assignee: Mitsubishi Electric Corporation, Tokyo (JP)

(21) Appl. No.: 18/015,085

(22) PCT Filed: Aug. 3, 2020
(86) PCT No.: PCT/JP2020/029642

§ 371 Date: Jan. 9, 2023

(51) Int. Cl. H01L 23/00

(52) U.S. Cl. CPC H01L 24/05; H01L 24/45; H01L 24/03; H01L 24/85; H01L 2224/04042; H01L 2224/05083; H01L 2224/05573; H01L 2224/05647; H01L 2224/05124; H01L 2224/05147; H01L 2224/05155; H01L 2224/45147; H01L 2224/02122; H01L 2224/03011; H01L 2224/85

(57) ABSTRACT

A semiconductor device is obtained, in which the impact of bonding of the wiring member on an underneath structure including a semiconductor element is reduced and thus the reliability is improved. The semiconductor device includes: a semiconductor element with a first main surface; a first metal member formed on the first main surface; a second metal member formed on an upper surface of the first metal member; a third metal member formed on an upper surface of the second metal member; a fourth metal member with copper as a principal component, formed on an upper surface of the third metal member; and a wiring member with copper as a principal component, bonded to an upper surface of the fourth metal member corresponding to a formation position of the third metal member.

### TECHNICAL FIELD

The present disclosure relates to a semiconductor device with an electrode structure for using copper wiring, a manufacturing method of the semiconductor device, and a power converter.

### BACKGROUND TECHNOLOGY

In recent years, it has been required for a semiconductor device for power applications to have a higher current density. In order to carry high density current, a semiconductor device that can withstand being driven under a high temperature condition is required. For such a semiconductor device, it is proposed to use copper wiring as metal wiring for connecting the semiconductor device to an external terminal.

There is a generally known bonding method in which ultrasonic vibration energy is applied to a metal wire with a diameter of about 100 μm to bond the metal wire to a semiconductor device. In this technique, the ultrasonic energy for bonding a copper wire as the metal wire is required to be greater than the ultrasonic energy for bonding an aluminum wire as the metal wire.

Thus, in a conventional semiconductor device, a large energy acts on the semiconductor element with an electrode formed thereon in order to bond the copper wire thereto. With the aim of reducing the impact of this energy on an underneath structure, a method to improve wire bonding performance by using a copper for the top surface of the electrode to which a copper wire is bonded and by forming, underneath the copper, a copper (Cu) with a higher Vickers hardness than that of the top surface copper or a nickel (Ni) is described (for example, Patent Document 1).

### PRIOR ART REFERENCES

### Patent Documents

[Patent Document 1] Japanese Unexamined Patent Application Publication No. 2018-37684

### SUMMARY OF THE INVENTION

### Problems to be Solved by the Invention

However, in the semiconductor device described in Patent Document 1, when a copper wire is bonded, if there is a material of low hardness underneath the material of high hardness, a crack caused in the material of high hardness will also develop into the aluminum of low hardness, resulting in deterioration of the reliability of the semiconductor device.

The present disclosure is made to solve the above-mentioned problem and aims to obtain a semiconductor device with improved reliability by reducing the impact on the underneath structure including a semiconductor element during bonding a metal wire.

### Means for Solving the Problem

A semiconductor device according to the present disclosure includes: a semiconductor element with a first main surface; a first metal member formed on the first main surface; a second metal member formed on an upper surface of the first metal member; a third metal member formed on an upper surface of the second metal member; a fourth metal member with copper as a principal component, formed on an upper surface of the third metal member; and a wiring member with copper as a principal component, bonded to an upper surface of the fourth metal member corresponding to a formation position of the third metal member.

### Effects of the Invention

According to the present disclosure, a second metal member is formed on an upper surface of a first metal member, a third metal member is formed on an upper surface of the second metal member, and a wiring member with copper as the principal component is provided on an upper surface of a fourth metal member corresponding to the formation position of the third metal member, so that the impact of bonding of the wiring member on an underneath structure including the semiconductor element can be reduced and the reliability of the semiconductor device can be improved.

### BRIEF DESCRIPTIONS OF DRAWINGS

FIG. 1 is a schematic diagram of a planar structure showing a semiconductor device according to Embodiment 1.

FIG. 2 is a schematic diagram of a cross-sectional structure showing the semiconductor device according to Embodiment 1.

FIG. 3 is a schematic diagram of a cross-sectional structure showing the semiconductor device according to Embodiment 1.

FIG. 4 is a schematic diagram of a planar structure showing another semiconductor device according to Embodiment 1.

FIG. 5 is a schematic diagram of a cross-sectional structure showing another semiconductor device according to Embodiment 1.

FIG. 6 is a schematic diagram of a cross-sectional structure showing another semiconductor device according to Embodiment 1.

FIG. 7 is a schematic diagram of a cross-sectional structure showing a manufacturing process of the semiconductor device according to Embodiment 1.

FIG. 8 is a schematic diagram of a cross-sectional structure showing a manufacturing process of the semiconductor device according to Embodiment 1.

FIG. 9 is a schematic diagram of a cross-sectional structure showing a manufacturing process of the semiconductor device according to Embodiment 1.

FIG. 10 is a schematic diagram of a cross-sectional structure showing a manufacturing process of the semiconductor device according to Embodiment 1.

FIG. 11 is a schematic diagram of a cross-sectional structure showing a manufacturing process of the semiconductor device according to Embodiment 1.

FIG. 12 is a schematic diagram of a cross-sectional structure showing a manufacturing process of the semiconductor device according to Embodiment 1.

FIG. 13 is a schematic diagram of a cross-sectional structure showing a semiconductor device according to Embodiment 2.

FIG. 14 is a schematic diagram of a cross-sectional structure showing another semiconductor device according to Embodiment 2.

FIG. 15 is a schematic diagram of a planar structure showing another semiconductor device according to Embodiment 2.

FIG. 16 is a schematic diagram of a planar structure showing another semiconductor device according to Embodiment 2.

FIG. 17 is a schematic diagram of a planar structure showing another semiconductor device according to Embodiment 2.

FIG. 18 is a schematic diagram of a planar structure showing another semiconductor device according to Embodiment 2.

FIG. 19 is a schematic diagram of a cross-sectional structure showing a manufacturing process of the semiconductor device according to Embodiment 2.

FIG. 20 is a schematic diagram of a cross-sectional structure showing a manufacturing process of the semiconductor device according to Embodiment 2.

FIG. 21 is a schematic diagram of a cross-sectional structure showing a manufacturing process of the semiconductor device according to Embodiment 2.

FIG. 22 is a schematic diagram of a cross-sectional structure showing a manufacturing process of the semiconductor device according to Embodiment 2.

FIG. 23 is a schematic diagram of a cross-sectional structure showing a manufacturing process of the semiconductor device according to Embodiment 2.

FIG. 24 is a schematic diagram of a cross-sectional structure showing a manufacturing process of another semiconductor device according to Embodiment 2.

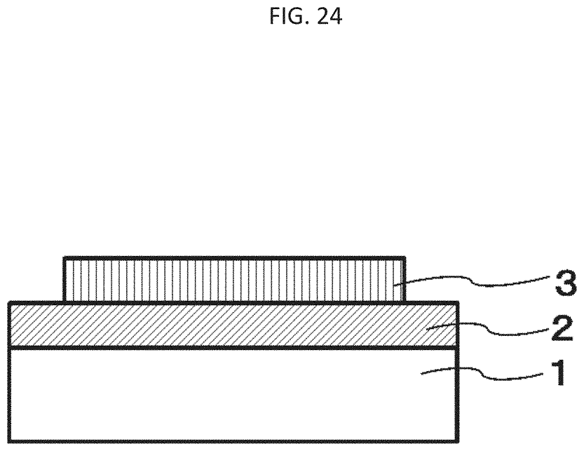

FIG. 25 is a schematic diagram of a planar structure showing a semiconductor device according to Embodiment 3.

FIG. 26 is a schematic diagram of a cross-sectional structure showing the semiconductor device according to Embodiment 3.

FIG. 27 is a schematic diagram of a cross-sectional structure showing another semiconductor device according to Embodiment 3.

FIG. 28 is a schematic diagram of a cross-sectional structure showing another semiconductor device according to Embodiment 3.

FIG. 29 is a schematic diagram of a cross-sectional structure showing another semiconductor device according to Embodiment 3.

FIG. 30 is a schematic diagram of a cross-sectional structure showing another semiconductor device according to Embodiment 3.

FIG. 31 is a schematic diagram of a cross-sectional structure showing another semiconductor device according to Embodiment 3.

FIG. 32 is a schematic diagram of a cross-sectional structure showing another semiconductor device according to Embodiment 3.

FIG. 33 is a schematic diagram of a cross-sectional structure showing another semiconductor device according to Embodiment 3.

FIG. 34 is a schematic diagram of a cross-sectional structure showing another semiconductor device according to Embodiment 3.

FIG. 35 is a schematic diagram of a cross-sectional structure showing another semiconductor device according to Embodiment 3.

FIG. 36 is a schematic diagram of a cross-sectional structure showing another semiconductor device according to Embodiment 3.

FIG. 37 is a schematic diagram of a cross-sectional structure showing another semiconductor device according to Embodiment 3.

FIG. 38 is a schematic diagram of a planar structure showing the semiconductor device according to Embodiment 4.

FIG. 39 is a schematic diagram of a planar structure showing another semiconductor device according to Embodiment 4.

FIG. 40 is a schematic diagram of a planar structure showing another semiconductor device according to Embodiment 4.

FIG. 41 is a schematic diagram of a planar structure showing another semiconductor device according to Embodiment 4.

FIG. 42 is a schematic diagram of a planar structure showing another semiconductor device according to Embodiment 4.

FIG. 43 is a schematic diagram of a planar structure showing another semiconductor device according to Embodiment 4.

FIG. 44 is a block diagram showing a configuration of a power conversion system to which a power converter according to Embodiment 5 is applied.

### EMBODIMENTS FOR CARRYING OUT THE INVENTION

First, overall configurations of the semiconductor device according to the present disclosure will be described with reference to the drawings. The figures are schematic and do not reflect the exact sizes, etc., of the components shown. The components with the same symbols are the same or equivalent, and this is common to the entire specification.

### Embodiment 1

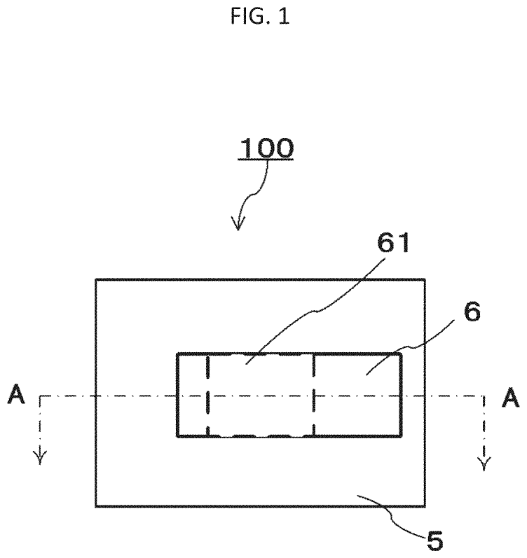

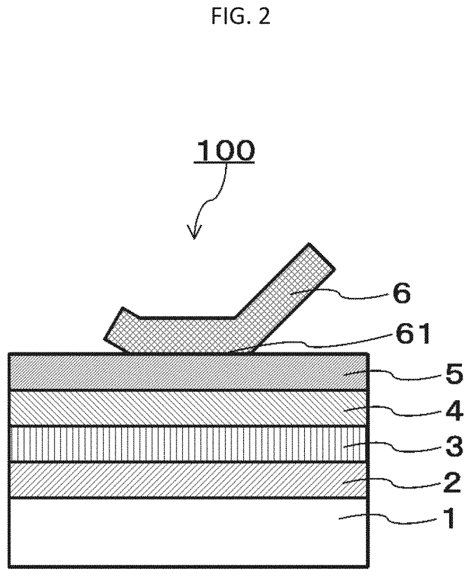

FIG. 1 is a schematic diagram of a planar structure showing a semiconductor device according to Embodiment 1. FIG. 2 is a schematic diagram of a cross-sectional structure showing the semiconductor device according to Embodiment 1. FIG. 2 is a schematic diagram of the cross-sectional structure along the alternate long and short dash line AA in FIG. 1.

In the figure, a semiconductor device 100 includes a semiconductor element 1, a first metal member 2, a second metal member 3, a third metal member 4, a fourth metal member 5, and a bonding wire 6, which is a wiring member, with copper as the principal component. The bonding wire 6 is bonded to an upper surface of the fourth metal member 5.

In the figure, the first metal member 2 is disposed (formed) on a first main surface of the semiconductor element 1. The second metal member 3 is formed on the upper surface of the first metal member 2. The third metal member 4 is formed on the upper surface of the second metal member 3. The fourth metal member 5 is formed on the upper surface of the third metal member 4. The bonding wire 6 with copper as the principal component is bonded to the upper surface of the fourth metal member 5. A bonding area 61 on the upper surface of the fourth metal member 5 is a bonding portion between the bonding wire 6 and the upper surface of the fourth metal member 5. The bonding wire 6 is bonded to the bonding area 61 on the upper surface of the fourth metal member 5.

In FIG. 1, the bonding area 61 between the bonding wire 6 and the fourth metal member 5 is shown by the dashed line. The bonding area 61 of the bonding wire 6 is disposed inside an outer edge of the fourth metal member 5. The bonding wire 6 is extended along a pair of opposite sides in the bonding area 61 of the bonding wire 6.

In FIG. 2, the bonding wire 6 bends away from the upper surface of the fourth metal member as the bonding wire 6 extends from the pair of opposite sides in the bonding area 61 of the bonding wire 6. In other words, the bonding wire 6 bends in a direction to increase the distance from the upper surface of the fourth metal member 5.

The semiconductor element 1 is, for example, a semiconductor element for power applications such as a metal oxide semiconductor field effect transistor (MOSFET) and an insulated gate bipolar transistor (IGBT). As a material for the semiconductor element 1, silicon (Si), silicon carbide (SiC), and gallium nitride (GaN) can be used.

However, the structure, material, and shape of the semiconductor element 1 are arbitrary as long as the first metal member 2, the second metal member 3, the third metal member 4, and the fourth metal member 5 can be formed on it. The thickness of the semiconductor element 1 may be from 50 μm to 500 μm and can be selected as appropriate depending on the applicable voltage and current rating of the semiconductor element 1.

The first metal member 2 is formed on the first main surface of the semiconductor element 1. As a material for the first metal member 2, for example, aluminum (Al) can be used. However, the material of the first metal member 2 is not limited to Al, but copper (Cu), nickel (Ni), tungsten (W), cobalt (Co), chromium (Cr), titanium (Ti) and their alloy materials can be used. The film thickness of the first metal member 2 ranges from 1 μm to 50 μm.

When Ni is used as the first metal member 2, a thicker Ni film improves the wire bonding performance, but an excessively thick Ni film increases film stress and thus increases the possibility of cracking. Therefore, the film thickness of the first metal member 2 preferably should be within a range from 5 μm to 20 μm.

The second metal member 3 is formed on the upper surface of the first metal member 2. As a material for the second metal member 3, for example, Cu can be used. The material for the second metal member 3 is not limited to Cu, but magnesium (Mg), iron (Fe), tin (Sn), palladium (Pd), and zinc (Zn) can also be used. The film thickness of the second metal member 3 ranges from 1 μm to 50 μm.

The third metal member 4 is formed on the upper surface of the second metal member 3. As a material for the third metal member 4, for example, Ni can be used. The material of the third metal member 4 is not limited to Ni, but Co, Cr, W, titanium nitride (TiN) and their alloy materials can be used. The film thickness of the third metal member 4 ranges from 1 μm to 50 μm. If Co or Cr is used as the material for the third metal member 4, the thickness of the third metal member 4 should be within the range of 1 μm to 20 μm, since these materials can be formed by plating.

The fourth metal member 5 is formed on the upper surface of the third metal member 4. For the fourth metal member 5, a material with Cu as the principal component can be used. The film thickness of the fourth metal member 5 ranges from 1 μm to 50 μm.

Here, the relationship among the materials of the first metal member 2, the second metal member 3, the third metal member 4, and the fourth metal member 5 will be described.

A material with Cu as the principal component is used for the bonding wire 6, described below, which is to be bonded to the fourth metal member 5. Therefore, considering the wire bondability of the bonding wire 6 to the first main surface of the semiconductor element 1, the material with Cu as the principal component is selected. And, in order to reduce the downward impact (damage) when the Cu bonding wire 6 is wire-bonded to the first main surface of the semiconductor element 1, a material with a hardness equal to or higher than that of the fourth metal member 5 is used for either the second metal member 3 or the third metal member 4. Here, the “hardness” used here is a value defined by, for example, Vickers hardness, but the same relationship applies even if another index of hardness is used.

In particular, the Ni, when used as the third metal member 4, serves as a damage suppression layer that prevents the impact (damage) generated during the wire bonding from propagating downward from the second metal member 3.

The second metal member 3 serves as a damage suppression layer that suppresses the damage due to the thermal stress caused by the heat generated when the semiconductor device 100 operates. Therefore, for the second metal member 3, a material with a hardness equal to or lower than that of the third metal member 4 is used.

The hardness of the material of the first metal member 2 is equal to or lower (softer) than the hardness of the second metal member 3 and the third metal member 4. As described above, by using, for the second metal member 3, a material with a hardness equal to or higher than that of the first metal member 2, the influence of the damage due to the thermal stress can be suppressed from being propagated to the first metal member 2. Regarding the hardness of the materials, using materials with the same hardness between the materials has a certain effect, but it is more effective to use materials with different hardness.

Specifically, the layer composition from the first metal member 2 to the fourth metal member 5 must include a Cu/Ni/Cu sandwich structure. In particular, it is desirable that the materials in the Cu/Ni/Cu sandwich structure be disposed contiguous to each other as in a case where Cu/Ni/Cu respectively correspond to the fourth metal member 5/the third metal member 4/the second metal member 3. Notwithstanding the above, the materials in the Cu/Ni/Cu sandwich structure do not necessarily need to be placed contiguous to each other, but it suffices as long as Ni is eventually disposed between Cu and Cu, as in the Cu/Ni/Cu layer structure realized by the layer composition of the fourth metal member 5/the second metal member 3/the first metal member 2 or the fourth metal member 5/the third metal member 4/the first metal member 2. Of the first metal member 2, the second metal member 3, and the third metal member 4, if a material other than Cu and Ni is used for the first metal member 2, Al can be selected for the material because Al is commonly used to form the first main surface of the semiconductor element 1. In this case, the structure from the first metal member 2 to the fourth metal member 5 will be an Al/Cu/Ni/Cu structure. As for other configurations, the layers other than the layers of Cu, Ni, and Cu can be selected from the metal members mentioned above, and these layers each are expected to serve as a barrier metal or an adhesion layer.

In addition to the first metal member 2, the second metal member 3, the third metal member 4, and the fourth metal member 5, a diffusion barrier layer or an adhesion layer may be inserted between the above metal members as appropriate. W Co, Cr, Ti, Pd, Pt and their alloys may be used as the diffusion barrier layer or the adhesion layer. Other materials may be used as well, as long as the effects of the present disclosure can be obtained.

Additionally, an antioxidant film may be additionally formed on the upper surface of the fourth metal member 5 to prevent oxidation from occurring, the oxidation starting from the upper surface of the fourth metal member 5. As the antioxidant film, an organic material or an inorganic material such as metal can be used. As a metal material for the antioxidant film, Au, Ag, Pd and Pt can be used. The antioxidant film should preferably be made of a precious metal material. However, the material is not limited to the above as long as the effects of the present disclosure are not compromised.

Thus, by providing the diffusion barrier layer between the metal members, interdiffusion of metal atoms between the layers can be suppressed. Also, by providing the adhesion layer between the metal members, adhesion between the layers can be improved. Furthermore, by providing the antioxidant film between the metal members, defects due to oxidation (insufficient adhesion) can be controlled.

The wiring member 6 is formed on the upper surface of the fourth metal member 5. The material for the wiring member 6 may be a material with Cu as the principal component. The wiring member 6 may contain as its component, in addition to Cu, a different material such as another metal or an organic component. Also, the surface of the wiring member 6 may be coated with another metal or an organic component. In terms of shape, the wiring member 6 may be a plate, a foil, or a wire. The best shape for the wiring member 6 is a wire shape. The thickness or the diameter of the wiring member 6 of the wire shape should preferably be from 100 μm to 500 μm. However, the structure, material and shape are not limited to the above as long as the effects of the present disclosure are not compromised.

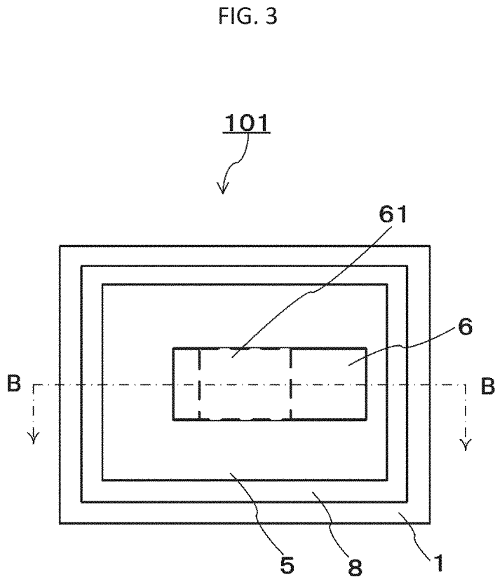

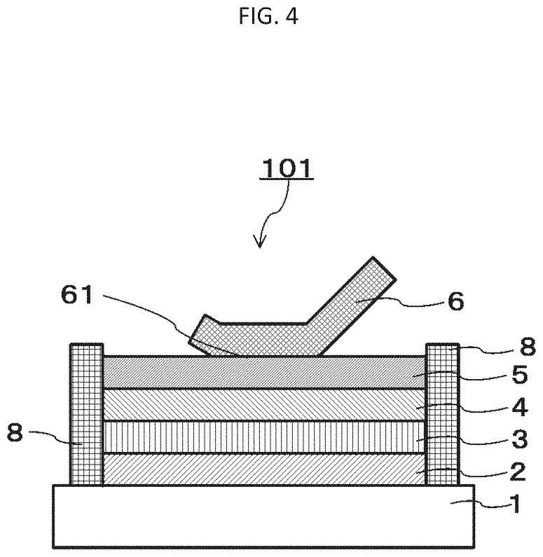

FIG. 3 is a schematic diagram of a planar structure showing another semiconductor device according to Embodiment 1. FIG. 4 is a schematic diagram of a cross-sectional structure showing another semiconductor device according to Embodiment 1. FIG. 4 is a schematic diagram of a cross-sectional structure along the alternate long and short dash line BB in FIG. 3.

In the figure, a semiconductor device 101 includes the semiconductor element 1, the first metal member 2, the second metal member 3, the third metal member 4, the fourth metal member 5, the bonding wire 6, which is the wiring member, with copper as the principal component, and an insulation member 8. The bonding wire 6 is bonded to the upper surface of the fourth metal member 5.

In FIG. 3, an outermost edge of the semiconductor device 100 is an outer edge of the semiconductor element 1. Inside the outer edge of the semiconductor element 1, there is an outer edge of the fourth metal member 5. The insulation member 8 is disposed around a perimeter (outer edge) of the fourth metal member 5. The bonding area 61 of the bonding wire 6 and the fourth metal member 5 is shown by the dashed line. The bonding area 61 of the bonding wire 6 is disposed inside the outer edge of the fourth metal member 5. The bonding wire 6 is extended along a pair of opposite sides in the bonding area 61 of the bonding wire 6.

In FIG. 4, the bonding wire 6 bends away from the upper surface of the fourth metal member 5 as the bonding wire 6 extends from the pair of opposite sides in the bonding area 61 of the bonding wire 6. In other words, outside the outer edge of the bonding area 61, the bonding wire 6 bends in the direction that increases the distance from the upper surface of the fourth metal member 5. The upper surface of the insulation member 8 is disposed higher than the upper surface of the fourth metal member 5. In other words, the upper surface of the insulation member 8 protrudes upward from the upper surface of the fourth metal member 5.

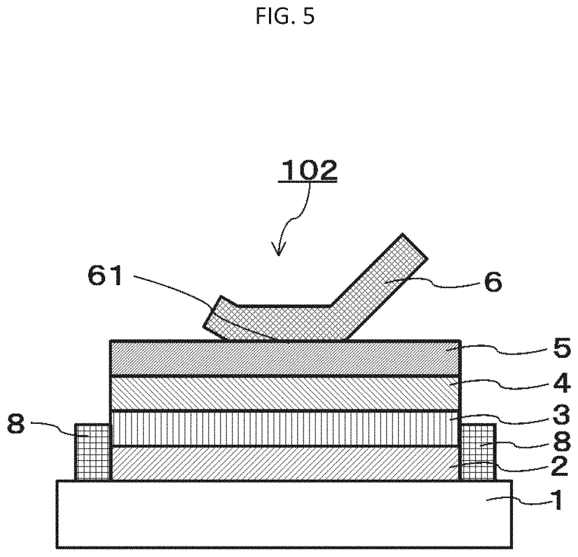

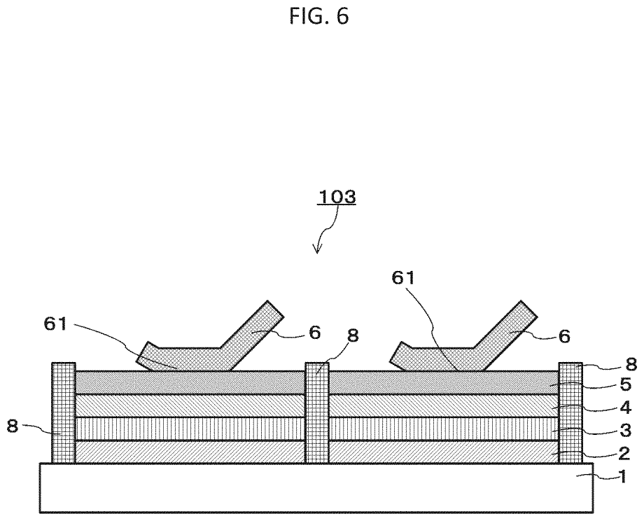

FIG. 5 is a schematic diagram of a cross-sectional structure showing another semiconductor device according to Embodiment 1. FIG. 6 is a schematic diagram of a cross-sectional structure showing another semiconductor device according to Embodiment 1.

In FIG. 5, the semiconductor device 102 has the same configuration as the semiconductor device 101 in FIG. 4, except the shape of the insulation member 8. Although in the semiconductor device 101 in FIG. 4, the upper surface of the insulation member 8 is disposed above the upper surface of the fourth metal member 5, in the semiconductor device 102, the upper surface of the insulation member 8 is disposed below the upper surface of the fourth metal member 5.

To allow the semiconductor device to perform its function, it is conceivable that its stacked metal members, namely, the first metal member 2, the second metal member 3, the third metal member 4, and the fourth metal member 5, be covered around their outer sides with the insulation member 8, which is made of an insulating material, in order to ensure insulation with the other areas. In this case, the insulation member 8 is disposed on the first main surface (upper surface) of the semiconductor element 1 because the semiconductor element 1 itself has a larger outer shape than the stacked metal members.

In FIG. 4, the insulation member 8 is in contact with the respective sides of the first metal member 2, the second metal member 3, the third metal member 4, and the fourth metal member 5. The upper surface of the insulation member 8 protrudes upward from the upper surface of the fourth metal member 5.

Unlike FIG. 4, in FIG. 5, the insulation member 8 only needs to be in contact with at least part of a side of one of the stacked metal members, namely the first metal member 2, the second metal member 3, the third metal member 4, and the fourth metal member 5.

As shown in FIG. 6, a plurality of the structures shown in FIG. 4 may be disposed side by side, with the insulation member 8 serving as a termination region of the semiconductor element 1. In a case where the plurality of structures shown in FIG. 4 are disposed side by side, regarding the configurations of the stacked metal members, if at least one of the plurality of structures disposed side by side has the structure shown in FIG. 4, other areas may have a structure different from that shown in FIG. 4. In a case where the insulation member 8 serves as the termination region of the semiconductor element 1, regarding the positional relation between the semiconductor element 1 and the insulation member 8, the insulation member 8 may be disposed inside the outer edge of the first main surface of the semiconductor element 1, or may be disposed flush with the termination region of the semiconductor element 1. Also, the insulation member 8 may protrude from the outer edge of the first main surface of the semiconductor element 1. Additionally, the insulation member 8 may be disposed covering the side of the semiconductor element 1 and the second main face (back surface), which is the opposite side of the first main surface.

The material for the insulation member 8 may be polyimide or the like, but any material can be used as long as the functionalities of the present disclosure are not compromised.

Next, the manufacturing method of the semiconductor device 100 according to the present embodiment will be described.

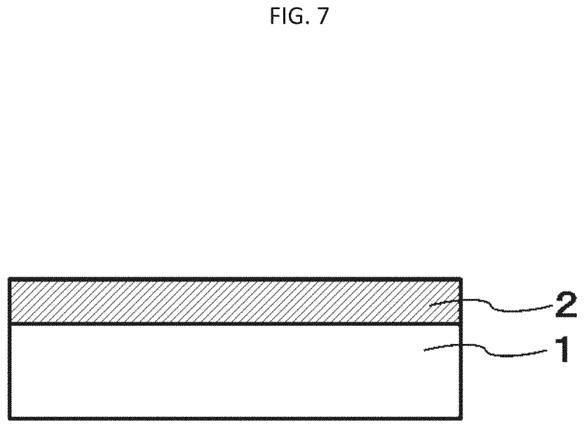

FIGS. 7 to 12 are each a schematic diagram of a cross-sectional structure showing a manufacturing process of the semiconductor device according to Embodiment 1.

The main manufacturing process of Embodiment 1 is roughly divided into six steps. The first step is a step of performing a process to make the semiconductor element 1 function as a semiconductor element (semiconductor element preparation step). The second step is a step of forming the first metal member 2 on the first main surface of the semiconductor element 1 (first metal member formation step). The third step is a step of forming the second metal member 3 on the upper surface of the first metal member 2 (second metal member formation step). The fourth step is a step of forming the third metal member 4 on the upper surface of the second metal member 3 (third metal member formation step). The fifth step is a step of forming the fourth metal member 5 on the upper surface of the third metal member 4 (fourth metal member formation step). The sixth step is a step of forming the bonding wire 6, which is the wiring member, on the upper surface of the fourth metal member 5 (wiring member formation step). Through these steps, the semiconductor device 100 can be manufactured.

In the first step, the semiconductor element 1 is processed to function as a semiconductor element.

Next, as shown in FIG. 7, in the second step, the first metal member 2 is formed on the first main surface of the semiconductor element 1. To form the first metal member 2, chemical vapor deposition (CVD method), physical vapor deposition (PVD method), or plating may be used. The plating includes two types: electroless plating and electrolytic plating. When using a plating method, regarding the details of the plating process, any process, method, and formation condition can be applied as long as the first metal member 2 can be formed. Any pre-process necessary to form a plating film may be performed as needed.

For example, sputtering film deposition may be used as the PVD method. Although there are many sputtering methods for the sputtering film deposition such as magnetron sputtering, evaporation, or ion beam sputtering, any sputtering method may be used as long as a targeted first metal member 2 can be formed.

Although there are two types of power supply, a direct current type and an alternating current type, to be used when performing the sputtering film deposition, any sputtering method may be used as long as the targeted first metal member 2 can be formed. Although the sputtering film deposition conditions include many setting parameters such as heated deposition or non-heated deposition, assisted deposition or non-assisted deposition, input power, and gas flow rate, any deposition condition may be used as long as the targeted first metal layer can be formed.

In a case where the electrolytic plating method is used to form the first metal member 2, it may be necessary to form a seed layer for plating film formation and an adhesion film for improving adhesion with the first main surface of the semiconductor element 1. Although the CVD method and the PVD method, mentioned above, can be used to form the seed layer and the adhesion layer, either of them may be used as long as the targeted film can be formed. However, in view of the configuration of the semiconductor element 1 or the film thicknesses required for the seed layer and the adhesion layer, the sputtering film deposition is desirable to form the seed layer and the adhesion layer.

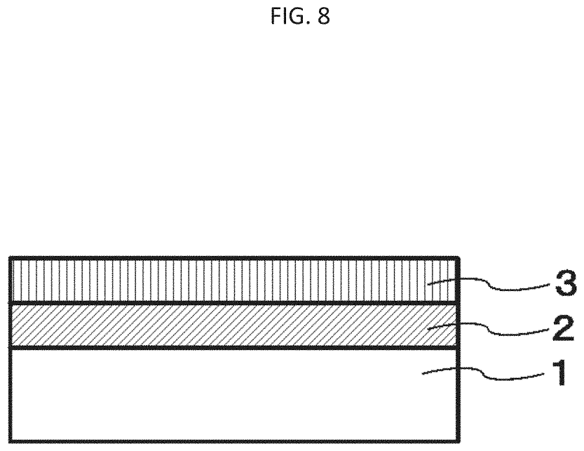

Next, as shown in FIG. 8, in the third step, the second metal member 3 is formed on the upper surface of the first metal member 2. To form the second metal member 3, the forming method similar to that used to form the first metal member 2 described above may be used.

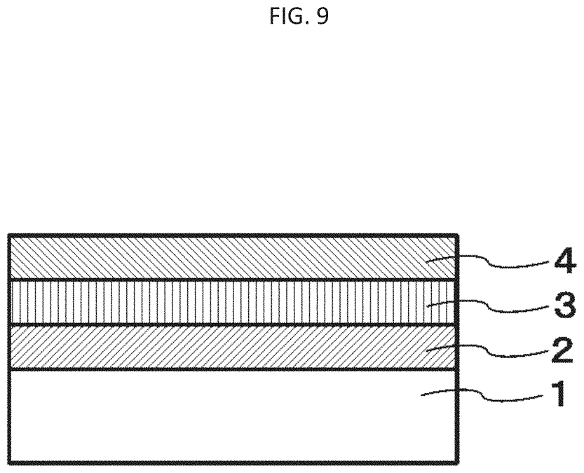

Next, as shown in FIG. 9, in the fourth step, the third metal member 4 is formed on the upper surface of the second metal member 3. To form the third metal member 4, the forming method similar to that used to form the first metal member 2 described above may be used.

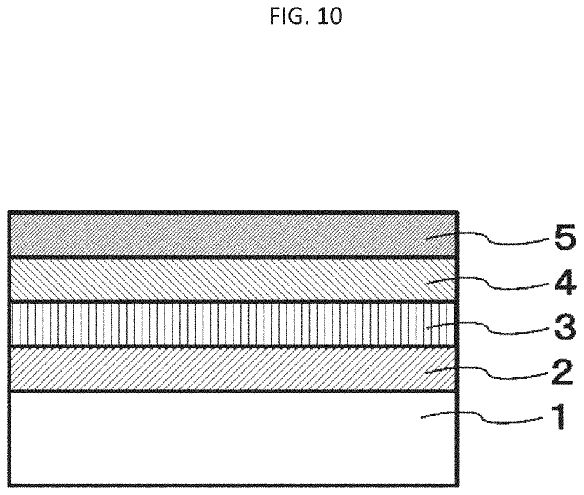

Next, as shown in FIG. 10, in the fifth step, the fourth metal member 5 is formed on the upper surface of the third metal member 4. To form the fourth metal member 5, the forming method similar to that used to form the first metal member 2 described above may be used.

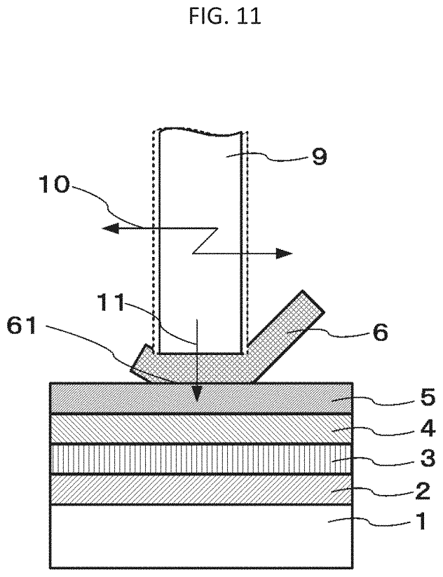

Next, as shown in FIG. 11, in the sixth step, the bonding wire 6 is formed on the upper surface of the fourth metal member 5. To form the bonding wire 6, bonding by thermocompression, bonding by ultrasonic energy, and bonding by a bonding material such as solder may be used. In view of the aim of the present disclosure, the bonding by ultrasonic energy is desirable to form the bonding wire 6. Although the bonding by ultrasonic energy involves various parameters such as load, amplitude, and processing time, any method or condition may be used as long as a targeted bonding result is obtained. By applying the ultrasonic energy by vibrating a tool 9 in the directions 10 parallel to the first main surface of the semiconductor element 1 with the tool 9 keeping pressing the bonding wire 6 in the direction 11 toward the upper surface of the fourth metal member 5, the upper surface of the fourth metal member 5 and the bonding wire 6 are bonded together in the bonding area 61.

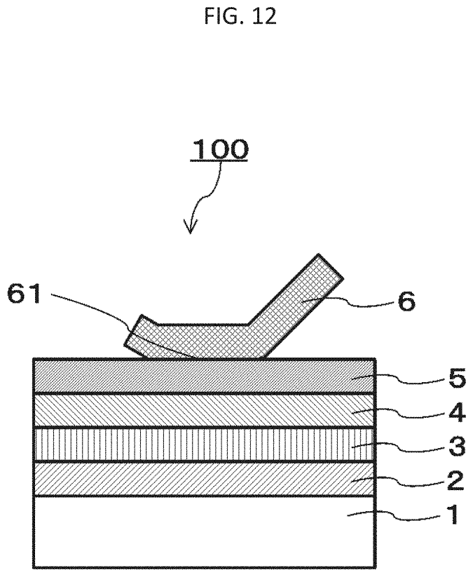

Through these steps, the semiconductor device 100 shown in FIG. 12 can be manufactured.

In the semiconductor device configured as described above, the second metal member 3 is formed on the upper surface of the first metal member 2, the third metal member 4 is formed on the upper surface of the second metal member 3, and the bonding wire 6 with copper as the principal component is provided on an upper surface of the fourth metal member 5 corresponding to the formation position of the third metal member 4, so that the impact of bonding of the bonding wire 6 on the underneath structure including the semiconductor element 1 can be reduced and the reliability of the semiconductor device can be improved.

### Embodiment 2

Embodiment 2 differs from Embodiment 1 in that at least the outer edge of the fourth metal member 5, from among the first metal member 2, the second metal member 3, the third metal member 4, and the fourth metal member 5, used in Embodiment 1, is disposed inside the outer edges of the other metal members. Stacking the metal members inevitably increases the total thickness of the metal members. The increase in the total film thickness of the metal members is likely to cause stress at the position where the semiconductor element 1 and a metal member are in direct contact, which may result in damaging the semiconductor element 1 such as cracking. As described above, the outer edge of the fourth metal member 5 is disposed inside the outer edge of at least one of the first metal member 2, the second metal member 3, and the third metal member 4, thereby reducing the total film thickness of the metal members at the contact position of the semiconductor element 1 and the metal member and thus reducing the stress generated in the semiconductor element 1. As a result, the occurrence of damage such as cracking to the semiconductor element 1 can be suppressed and the reliability of the semiconductor device 200 can be improved. Other respects are the same as in Embodiment 1, so that the detailed descriptions will be omitted.

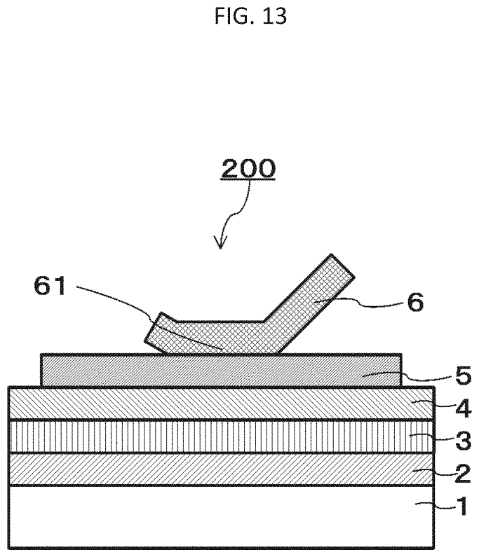

FIG. 13 is a schematic diagram of a cross-sectional structure showing the semiconductor device according to Embodiment 2. In the figure, the semiconductor device includes the semiconductor element 1, the first metal member 2, the second metal member 3, the third metal member 4, the fourth metal member 5, and the bonding wire 6, which is the wiring member, with copper as the principal component. The bonding wire 6 is bonded to the upper surface of the fourth metal member 5.

In FIG. 13, the first metal member 2 is formed (bonded) on the first main surface of the semiconductor element 1. The second metal member 3 is formed on the upper surface of the first metal member 2. The third metal member 4 is formed on the upper surface of the second metal member 3. The fourth metal member 5 is formed on the upper surface of the third metal member 4. The bonding wire 6 with copper as the principal component is bonded to the upper surface of the fourth metal member 5. The bonding area 61 on the upper surface of the fourth metal member 5 is the bonding portion between the bonding wire 6 and the upper surface of the fourth metal member 5. The bonding wire 6 is bonded to the bonding area 61 on the upper surface of the fourth metal member 5. The outer edge of the fourth metal member 5 is disposed inside the outer edges of the first metal member 2, the second metal member 3, and the third metal member 4.

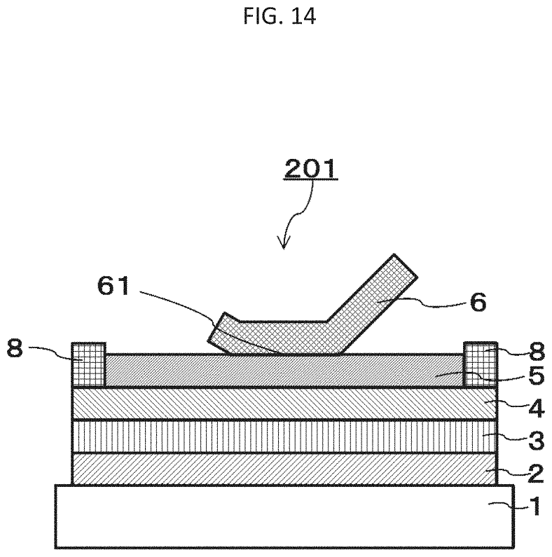

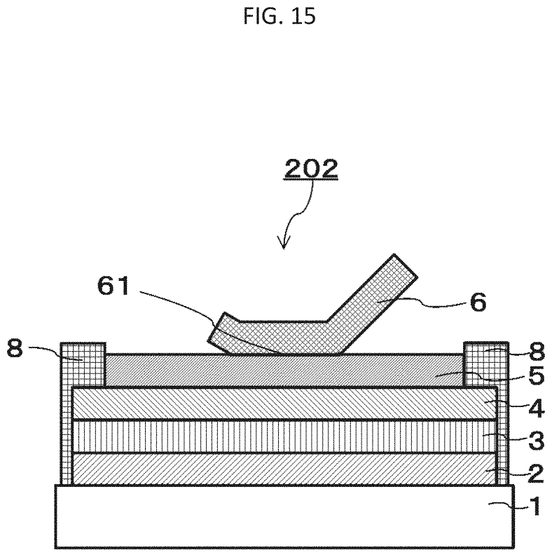

FIG. 14 is a schematic diagram of a cross-sectional structure showing another semiconductor device according to Embodiment 2. FIG. 15 is a schematic diagram of a planar structure showing another semiconductor device according to Embodiment 2. In FIG. 14, the insulation member 8 is disposed in a peripheral area of the upper surface of the third metal member 4, the peripheral area being located outside the outer edge of the fourth metal member 5. The insulation member 8 is in contact with the side of the fourth metal member 5. The upper surface of the insulation member 8 protrudes upward from the upper surface of the fourth metal member 5. In FIG. 15, the insulation member 8 is disposed in contact with the side of the fourth metal member 5 and in contact, from the peripheral area of the upper surface of the third metal member 4 to the first main surface of the semiconductor element 1, with the sides of the third metal member 4, the second metal member 3, and the second metal member 3.

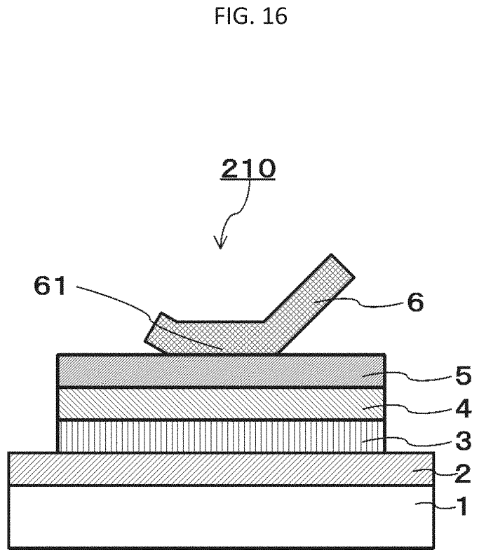

FIG. 16 is a schematic diagram of a cross-sectional structure showing another semiconductor device according to Embodiment 2. In FIG. 16, the second metal member 3 and the third metal member 4 of the semiconductor device 200 shown in FIG. 13 have the same outer shape (outer edge) as that of the fourth metal member 5. In the figure, the semiconductor device includes the semiconductor element 1, the first metal member 2, the second metal member 3, the third metal member 4, the fourth metal member 5, and the bonding wire 6, which is the wiring member, with copper as the principal component. The bonding wire 6 is bonded to the upper surface of the fourth metal member 5.

In FIG. 16, the first metal member 2 is formed (bonded) on the first main surface of the semiconductor element 1. The second metal member 3 is formed on the upper surface of the first metal member 2. The third metal member 4 is formed on the upper surface of the second metal member 3. The fourth metal member 5 is formed on the upper surface of the third metal member 4. The bonding wire 6 with copper as the principal component is bonded to the upper surface of the fourth metal member 5. The bonding area 61 on the upper surface of the fourth metal member 5 is the bonding portion between the bonding wire 6 and the upper surface of the fourth metal member 5. The bonding wire 6 is bonded to the bonding area 61 on the upper surface of the fourth metal member 5. The outer edges of the second metal member 3, the third metal member 4, and the fourth metal member 5 are of the same size and the outer edge of the first metal member 2 is disposed outside the outer edge of the second metal member 3.

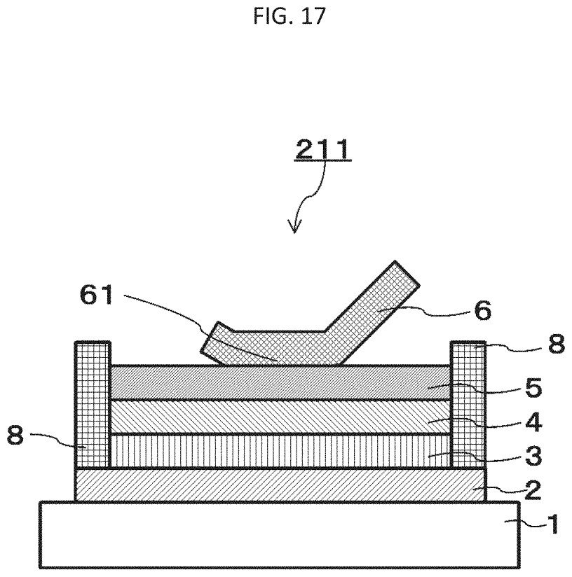

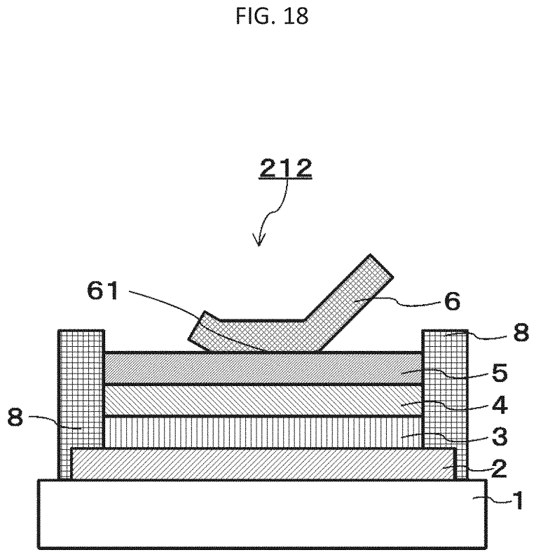

FIG. 17 is a schematic diagram of a cross-sectional structure showing another semiconductor device according to Embodiment 2. FIG. 18 is a schematic diagram of a planar structure showing another semiconductor device according to Embodiment 2. In FIG. 17, the insulation member 8 is disposed in the peripheral area of the upper surface of the first metal member 2, the peripheral area being located outside the outer edge of the fourth metal member 5. The insulation member 8 is in contact with the sides of the fourth metal member 5, the third metal member 4, and the second metal member 3. The upper surface of the insulation member 8 protrudes upward from the upper surface of the fourth metal member 5. In FIG. 18, the insulation member 8 is disposed in contact with the sides of the fourth metal member 5 to the second metal member 3 to reach the peripheral area of the upper surface of the first metal member 2 and the first main surface of the semiconductor element 1.

Thus, the insulation member 8 should be disposed around at least one of the first metal member 2, the second metal member 3, the third metal member 4, and the fourth metal member 5. The insulation member 8 may be disposed around the fourth metal member 5 in contact with the side of the fourth metal member 5 on the upper surface of the third metal member 4. Alternatively, the insulation member 8 may be disposed around the second metal member 3, the third metal member 4, and the fourth metal member 5 in contact with the sides of the second metal member 3, the third metal member 4, and the fourth metal member 5 to reach the upper surface of the first metal member 2. Further alternatively, the insulation member 8 may be disposed around the second metal member 3, the third metal member 4, and the fourth metal member 5 in contact with the sides of the second metal member 3, the third metal member 4, and the fourth metal member 5 to reach the upper surface of the first metal member 2. In this case, the insulation member 8 may be disposed in contact with the side of the first metal member 2 to reach the first main surface of the semiconductor element 1.

As described above, the outer edge of the fourth metal member 5 is disposed inside the outer edge of at least one of the first metal member 2, the second metal member 3, and the third metal member 4, thereby suppressing the occurrence of damage such as cracking to the semiconductor element 1 due to stress and thus improving the reliability of the semiconductor device 200. The same effect can be obtained by disposing the outer edge of the fourth metal member 5 inside any plurality of the outer edges of the first metal member 2, the second metal member 3, and the third metal member 4.

For example, the outer edges of the third metal member 4 and the fourth metal member 5, being flush with each other, can be disposed inside the outer edges of the first metal member 2 and the second metal member 3, being flush with each other.

Alternatively, the outer edges of the second metal member 3, the third metal member 4, and the fourth metal member 5, being flush with each other, can be disposed inside the outer edge of the first metal member 2. Alternatively, the outer edge of the fourth metal member 5 can be disposed inside the flush outer edges of the first metal member 2, the second metal member 3, and the third metal member 4.

To increase the effectiveness of the present disclosure, the outer edge of the second metal member 3 should be inside the outer edge of the first metal member 2. Even when the outer edge of the fourth metal member 5 is disposed outside one of or both of the outer edges of the second metal member 3 and the third metal member 4, the outer edge of the fourth metal member 5 should be disposed inside at least one of the outer edges of the first metal member 2, the second metal member 3, and the third metal member 4.

Such stacking of the metal members inevitably increases the total thickness of the metal members. The increase in the total film thickness of the metal members is likely to cause stress at the position where the semiconductor element 1 and a metal member are in direct contact, which may result in damaging the semiconductor element 1 such as cracking.

However, the total film thickness of the metal members at the contact position of the semiconductor element 1 and the metal member can be reduced and thus the stress generated in the semiconductor element 1 can be reduced, for example, by forming the outer edge of the fourth metal member 5 inside the outer edge of at least one of the first metal member 2, the second metal member 3, and the third metal member 4. As a result, the occurrence of damage such as cracking to the semiconductor element 1 can be suppressed and the reliability of the semiconductor device 200 can be improved.

Next, the manufacturing method of the semiconductor device 200 according to the present embodiment will be described.

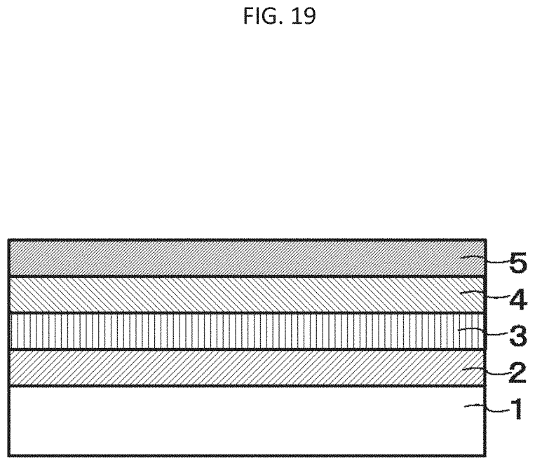

FIGS. 19 to 23 are each a schematic diagram of a cross-sectional structure showing a manufacturing process of the semiconductor device according to Embodiment 2.

In order to dispose the outer edge of the fourth metal member 5 shown in FIG. 14 inside the outer edge of at least one of the first metal member 2, the second metal member 3, and the third metal member 4, a resist material or a metal mask, for example, may be used to limit the formation area of the metal member.

When the resist material is used, the outer edge of the fourth metal member 5 can be disposed inside the outer edge of the third metal member 4 by the following steps.

First, through the steps up to the fifth step shown in Embodiment 1, the first metal member 2, the second metal member 3, the third metal member 4, and the fourth metal member 5 are stacked on the first main surface of the semiconductor element 1, as shown in FIG. 19. Here, the following steps are performed before proceeding to the sixth step.

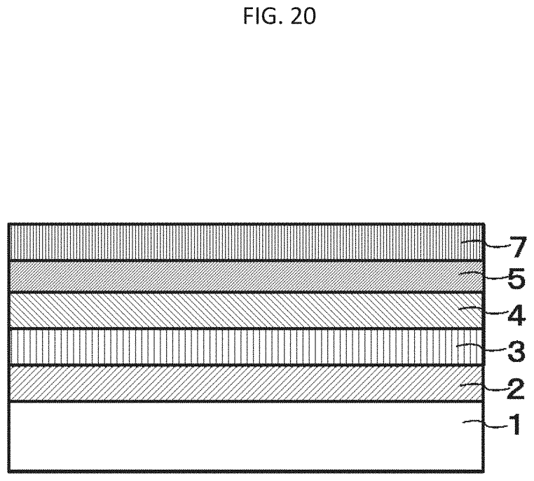

Next, as shown in FIG. 20, a resist material 7 is applied to the upper surface of the fourth metal member 5 as the seventh step (resist material application step). A positive resist or a negative resist can be used for the resist material 7. In a case where a photoresist is used as the resist material 7, regarding formation steps of a resist pattern on the semiconductor element 1 with the metal members up to the fourth metal member 5 formed, first, the resist material 7 is applied and spin coated on the upper surface of the fourth metal member 5 over the semiconductor element 1 with the metal members up to the fourth metal member 5 formed, so that the resist material 7 is wet spread evenly on the entire top surface over the semiconductor element 1 with the metal members up to the fourth metal member 5 formed.

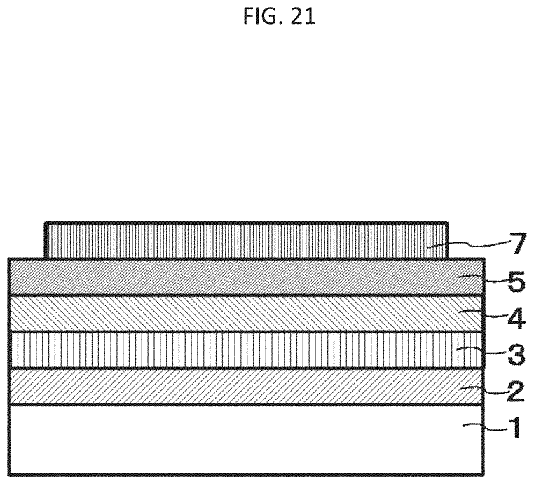

Next, as shown in FIG. 21, in the eighth step, a photo mask with a predetermined pattern is placed over the semiconductor element 1 with the metal members up to the fourth metal member 5 formed and the resist material 7 evenly wet spread, and then ultraviolet rays are applied by an exposure machine (photolithography step). After the application of the ultraviolet rays, the semiconductor element 1 with the metal members up to the fourth metal member 5 formed and the applied resist material 7 exposed to the ultraviolet rays is immersed in a developing solution to remove the resist material 7 in the area not cured by exposure to the ultraviolet rays (photolithography step).

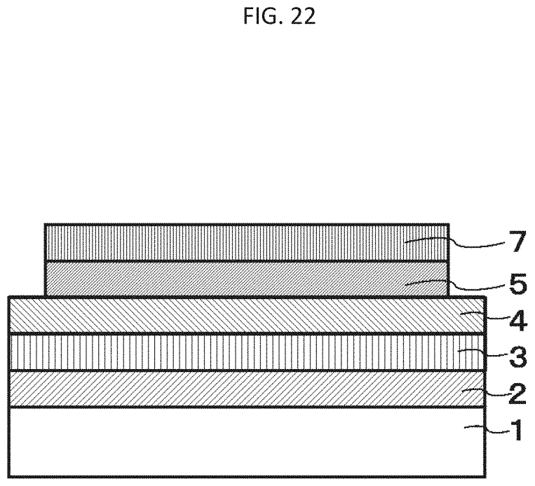

Next, as shown in FIG. 22, in the ninth step, in the semiconductor element 1 with the un-cured resist material 7 removed and the upper surface of the fourth metal member 5 exposed, the area where the resist material 7 is removed is etched, using the cured resist material 7 as the mask (metal member processing step). Wet etching or dry etching can be used to etch the fourth metal member 5. Any etching method can be used to etch the fourth metal member 5 as long as a targeted etching result can be obtained.

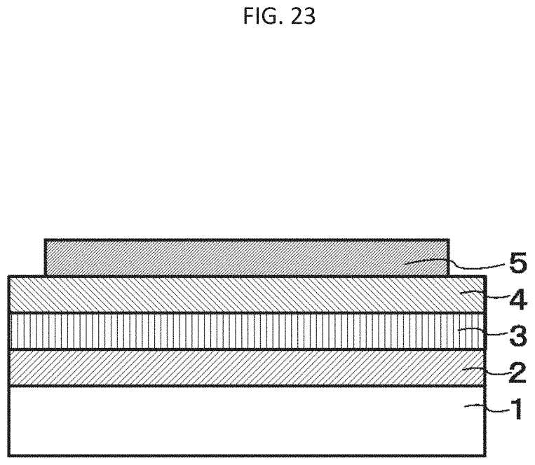

Next, as shown in FIG. 23, by removing the resist material 7 in the tenth step, a desired pattern of the fourth metal member 5 can be formed (resist material removal step). To remove the resist material 7, wet etching or dry etching can be used. To remove the resist material 7 leaving the targeted shape intact, it is better to selectively remove the resist material by wet etching. As for the etching solution to be used for the wet etching, any etching solution can be used as long as the resist material 7 can be removed with the targeted shape of the fourth metal member 5 maintained intact.

When etching the fourth metal member 5 using a metal mask, the metal mask is placed on the upper surface of the semiconductor element 1 with the fourth metal member 5 formed and sputter etching is performed to form the fourth metal member 5 into a desired shape.

Although in the above example, the fourth metal member 5 is formed on the upper surface of the third metal member 4 with the outer edge of the fourth metal member 5 disposed inside the outer edge of the third metal member 4, also the second metal member 3 can be formed by using the similar method, as shown in FIG. 23, on the upper surface of the first metal member 2 with the outer edge of the second metal member 3 disposed inside the outer edge of the first metal member 2. The metal members and the bonding wire 6 can be formed in the same manner as in Embodiment.

In the semiconductor device configured as described above, the second metal member 3 is formed on the upper surface of the first metal member 2, the third metal member 4 is formed on the upper surface of the second metal member 3, and the bonding wire 6 with copper as the principal component is provided on an upper surface of the fourth metal member 5 corresponding to the formation position of the third metal member 4, so that the impact of bonding of the bonding wire 6 on the underneath structure including the semiconductor element 1 can be reduced and the reliability of the semiconductor device can be improved.

Also, the outer edge of the fourth metal member 5 is disposed inside the outer edge of at least one of the first metal member 2, the second metal member 3, and the third metal member 4, thereby reducing the total film thickness of the metal members at the contact position of the semiconductor element 1 and a metal member and thus reducing the stress generated in the semiconductor element 1. As a result, the occurrence of damage such as cracking to the semiconductor element 1 can be suppressed and the reliability of the semiconductor device can be improved.

### Embodiment 3

Embodiment 3 differs from Embodiment 1 and Embodiment 2 in that the insulation member 8 is disposed (inserted) in the peripheral area of at least one of the interfaces of the contiguous metal members from among the first metal member 2, the second metal member 3, the third metal member 4, and the fourth metal member 5, which are used in Embodiment 1 and Embodiment 2. The disposed insulation member 8 in the peripheral area of the stacked contiguous metal members as described above can reduce the occurrence of stress in the peripheral area of the semiconductor element 1. As a result, the insulation member 8, which is softer than the metal members, can suppress the stress generation in the peripheral areas of the metal members, where stresses are likely to occur, and can suppress the occurrence of damage such as cracking in the semiconductor element 1, thereby improving the reliability of the semiconductor device. Other respects are the same as in Embodiment 1 and Embodiment 2, so that the detailed descriptions will be omitted. Note that the insulation member 8 is in contact with and surrounds the side of at least one of the first metal member 2, the second metal member 3, the third metal member 4, and the fourth metal member 5. The insulation member 81 is disposed in the peripheral area of at least one of the first metal member 2, the second metal member 3, the third metal member 4, and the fourth metal member 5.

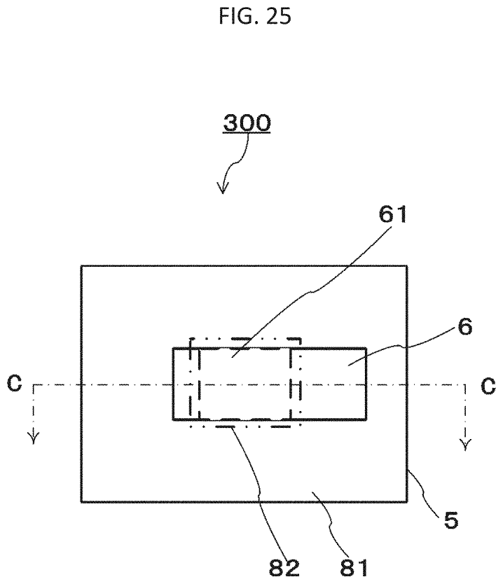

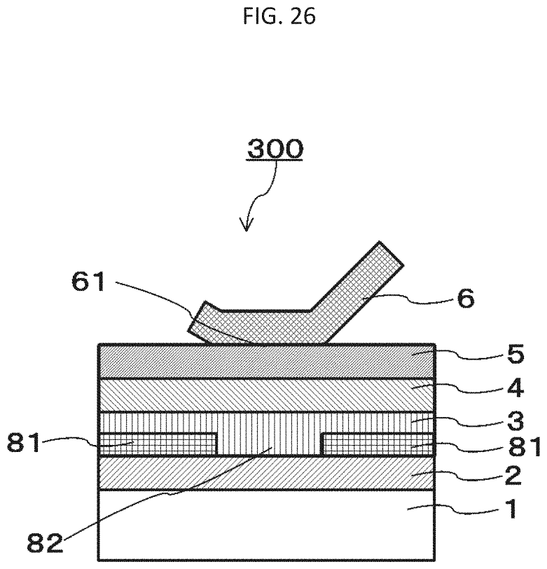

FIG. 25 is a schematic diagram of a planar structure showing a semiconductor device according to Embodiment 3. FIG. 26 is a schematic diagram of a cross-sectional structure showing the semiconductor device according to Embodiment 3. FIG. 26 is a schematic diagram of a cross-sectional structure along the alternate long and short dash line CC in FIG. 25.

In the figure, a semiconductor device 300 includes the semiconductor element 1, the first metal member 2, the second metal member 3, the third metal member 4, the fourth metal member 5, the bonding wire 6, which is the wiring member, with copper as the principal component, and the insulation member 81.

In FIG. 25, the bonding area 61 between the bonding wire 6 and the fourth metal member 5 is shown by the dashed line. The bonding area 61 of the bonding wire 6 is disposed inside the outer edge of the fourth metal member 5. The bonding wire 6 is extended along a pair of opposite sides in the bonding area 61 of the bonding wire 6. The insulation member 81 is disposed inside the outer edge of the fourth metal member 5. The insulation member 81 has an opening 82 at a position corresponding to the bonding area 61. The opening 82 of the insulation member 81 is shown by the chain double-dashed line. The inner edge of the insulation member 81 matches the outer edge of the opening 82.

In FIG. 26, the insulation member 81 is disposed in the peripheral area of the upper surface of the first metal member 2. The insulation member 81 is absent in the area corresponding to the bonding area 61 where the bonding wire 6 is bonded to the upper surface of the fourth metal member 5. In the insulation member 8, the opening 82 is provided in the area corresponding to the bonding area 61. The thickness of the second metal member 3 at the opening 82 of the insulation member 81 is thicker than the thickness of the second metal member 3 at the upper surface of the insulation member 8 by the thickness of the insulation member 81. Thus, the shape of the second metal member 3 is such that the lower-surface side thereof protrudes in its center toward the upper surface of the first metal member 2. The upper surface of the second metal member 3 is flat. Since the third metal member 4 is disposed on the flat upper surface of the second metal member 3, the third metal member 4 has flat upper and lower surfaces. Similarly, since the fourth metal member 5 is disposed on the flat upper surface of the third metal member 4, the fourth metal member 5 has flat upper and lower surfaces.

The insulation member 8 disposed between the layers of the first metal member 2 and the second metal member 3 divides (insulates from each other) the first metal member 2 and the second metal member 3 vertically in the peripheral area of the first metal member 2 where the insulation member 81 is disposed. Thus, using the insulation member 81 of lower hardness (softer) than the metal members, the first metal member 2 and the second metal member 3 are divided, so that the thickness of the metal members contributing to the stress generation is reduced compared to when the metal members are continuously stacked. This makes it possible to suppress the stress generation. Thus, by inserting the insulation member 81, the stress applied to the semiconductor element 1 can be reduced, which leads to reducing damage to the semiconductor element 1 caused by cracking and thus improving the reliability of the semiconductor device 200.

However, if the length of the insulation member 81, formed in the peripheral area of the first metal member 2, from the outer edge of the first metal member 2 toward the inside is too short, the reduction amount of the metal members is small and thus the stress relaxation effect is limited. As a result, the effect of controlling damage, such as caused by cracking, to the semiconductor element 1 is also limited. Conversely, if the length of the insulation member 81 from the outer edge of the first metal member 2 is too long, the area covered by the insulation member 81 on the upper surface of the first metal member 2 is too extensive. If the insulation member 81 with low heat dissipation extensively covers the upper surface of the first metal member 2, heat dissipation from the semiconductor device 200 is hindered. Therefore, the length of the insulation member 81 from the outer edge of the first metal member 2 should preferably be from 10 μm to 100 μm. In other words, the length of the second metal member 3 existing on the upper surface of the insulation member 81 should be from 10 μm to 100 μm.

Polyimide, for example, may be used as a material for the insulation member 81. However, the material is not limited to this as long as the similar effects can be achieved. In particular, a material of lower hardness than the metal members is desirable.

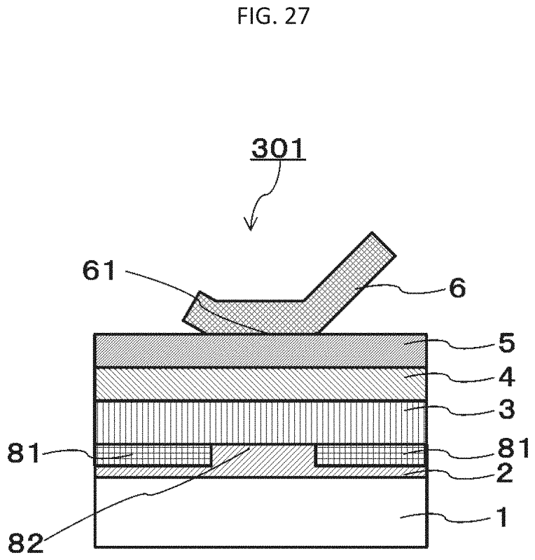

FIG. 27 is a schematic diagram of a cross-sectional structure showing another semiconductor device according to Embodiment 3.

In the figure, a semiconductor device 301 includes the semiconductor element 1, the first metal member 2, the second metal member 3, the third metal member 4, the fourth metal member 5, the bonding wire 6, which is the wiring member, with copper as the principal component, and the insulation member 81.

In FIG. 27, the insulation member 81 is disposed in the peripheral area on the lower surface of the second metal member 3. The insulation member 81 is absent in the area corresponding to the bonding area 61 where the bonding wire 6 is bonded to the upper surface of the fourth metal member 5. The opening 82 is provided in the area of the insulation member 81 corresponding to the bonding area 61. The thickness of the first metal member 2 disposed in the opening 82 of the insulation member 81 is thicker by the thickness of the insulation member 8 than the thickness of the first metal member 2 disposed in contact with the lower surface of the insulation member 81. In other words, the thickness of the peripheral area of the first metal member 2 where the insulation member 81 is disposed is thinner by the thickness of the insulation member 81 than the thickness of the first metal member 2 in the opening 82. In terms of shape, the first metal member 2 protrudes in its center toward the lower surface of the second metal member 3. The upper surface of the second metal member 3 is flat. Since the third metal member 4 is disposed on the flat upper surface of the second metal member 3, the third metal member 4 has flat upper and lower surfaces. Similarly, since the fourth metal member 5 is disposed on the flat upper surface of the third metal member 4, the fourth metal member 5 has flat upper and lower surfaces.

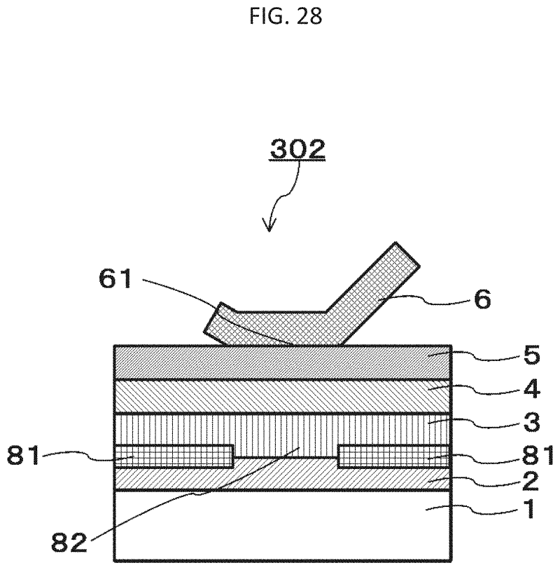

FIG. 28 is a schematic diagram of a cross-sectional structure showing another semiconductor device according to Embodiment 3.

In the figure, a semiconductor device 302 includes the semiconductor element 1, the first metal member 2, the second metal member 3, the third metal member 4, the fourth metal member 5, the bonding wire 6, which is the wiring member, with copper as the principal component, and the insulation member 81.

In FIG. 28, in terms of shape, the semiconductor device 302 has a shape of combination of the shape of the semiconductor device 300 and the shape of the semiconductor device 301. The insulation member 81 is disposed across (on both sides of) the interface between the first metal member 2 and the second metal member 3. In terms of shape, therefore, the first metal member 2 protrudes in its center toward the lower surface of the second metal member 3. The second metal member 3 protrudes in its center toward the upper surface of the first metal member 2. The protrusion of the first metal member 2 and the protrusion of the second metal member 3 are in contact to each other and surrounded by the insulation member 81.

In FIG. 28, the insulation member 81 is absent in the area corresponding to the bonding area 61 where the bonding wire 6 is bonded to the upper surface of the fourth metal member 5. The opening 82 is provided in the area of the insulation member 81 corresponding to the bonding area 61. The thickness of the first metal member 2 disposed in the opening 82 of the insulation member 81 is thicker by the corresponding thickness of the insulation member 81 than the thickness of the first metal member 2 disposed in contact with the lower surface of the insulation member 81. The thickness of the second metal member 3 disposed in the opening 82 of the insulation member 81 is thicker by the corresponding thickness of the insulation member 81 than the thickness of the second metal member 3 disposed on the upper surface of the insulation member 81. The thickness of the first metal member 2 disposed in the opening 82 of the insulation member 81 is thicker by the corresponding thickness of the insulation member 81 than the thickness of the first metal member 2 disposed in contact with the lower surface of the insulation member 81. In other words, the thickness of the peripheral area of the first metal member 2 where the insulation member 81 is disposed is thinner by the corresponding thickness of the insulation member 81 than the thickness of the first metal member 2 in the opening 82. The upper surface of the second metal member 3 is flat. Since the third metal member 4 is disposed on the flat upper surface of the second metal member 3, the third metal member 4 has flat upper and lower surfaces. Similarly, since the fourth metal member 5 is disposed on the flat upper surface of the third metal member 4, the fourth metal member 5 has flat upper and lower surfaces.

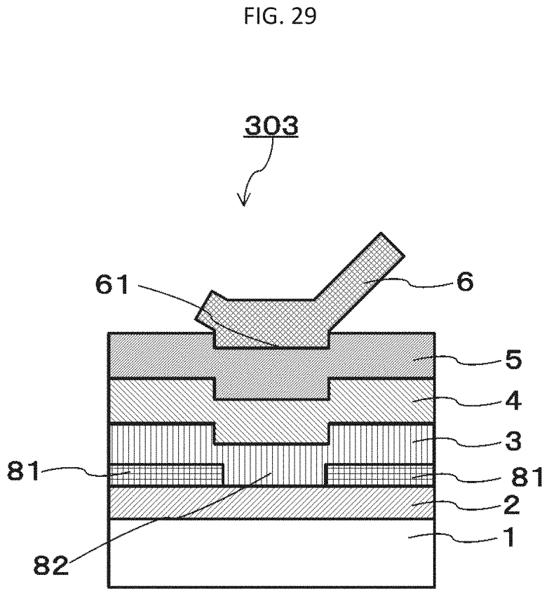

FIG. 29 is a schematic diagram of a cross-sectional structure showing another semiconductor device according to Embodiment 3.

In the figure, a semiconductor device 303 includes the semiconductor element 1, the first metal member 2, the second metal member 3, the third metal member 4, the fourth metal member 5, the bonding wire 6, which is the wiring member, with copper as the principal component, and the insulation member 81.

In FIG. 29, the semiconductor device 303 has a shape formed by disposing the second metal member 3, the third metal member 4, the fourth metal member 5, and the bonding wire 6 in accordance with (while maintaining) an upper shape formed when the insulation member 81 is disposed in the peripheral area of the upper surface of the first metal member 2 in the manufacturing process of the semiconductor device 300. Thus, as for the shapes of the metal members, the second metal member 3, the third metal member 4, and the fourth metal member 5 each are convex downward (concave upward) in their respective areas corresponding to the opening 82 of the insulation member 81. The bonding wire 6 also is convex downward in the bonding area 61 in accordance with the shape of the fourth metal member 5.

In FIG. 29, the insulation member 81 is disposed in the peripheral area of the upper surface of the first metal member 2. The insulation member 81 is absent in the area corresponding to the bonding area 61 where the bonding wire 6 is bonded to the upper surface of the fourth metal member 5. The opening 82 is provided in the area of the insulation member 81 corresponding to the bonding area 61. Although the thickness of the second metal member 3 is uniform regardless of the formation position, in other words, whether the insulation member 81 is present or absent, the second metal member 3 is depressed (dented) by the thickness of the insulation member 81 at the opening 82 of the insulation member 81. Since the third metal member 4 and the fourth metal member 5 are stacked on the upper surface of the second metal member 3, their shapes are similar to that of the underlying second metal member 3, accordingly. The bonding area 61 where the bonding wire 6 is bonded to the upper surface of the fourth metal member 5 is within the dent of the fourth metal member 5, the dent corresponding to the opening 82 of the insulation member 81. Thus, the bonding wire 6 protrudes in the area corresponding to the bonding area 61.

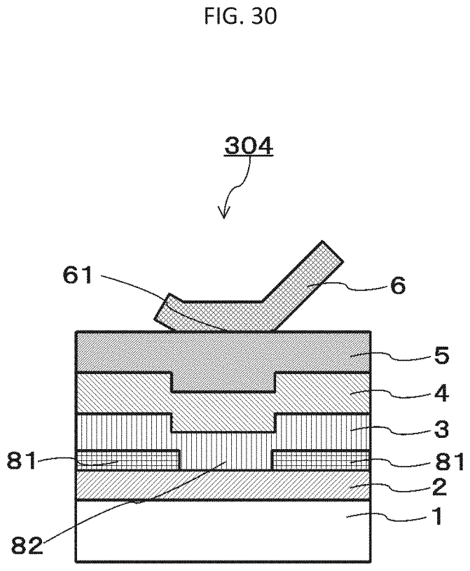

FIG. 30 is a schematic diagram of a cross-sectional structure showing another semiconductor device according to Embodiment 3.

In the figure, a semiconductor device 304 includes the semiconductor element 1, the first metal member 2, the second metal member 3, the third metal member 4, the fourth metal member 5, the bonding wire 6, which is the wiring member, with copper as the principal component, and the insulation member 81.

In FIG. 30, the semiconductor device 304 has a shape in which the upper surface of the fourth metal member 5 of the semiconductor device 303 shown in FIG. 28 is flattened. Except for the shape mentioned above, the semiconductor device 304 has the same shape as the semiconductor device 303 shown in FIG. 28.

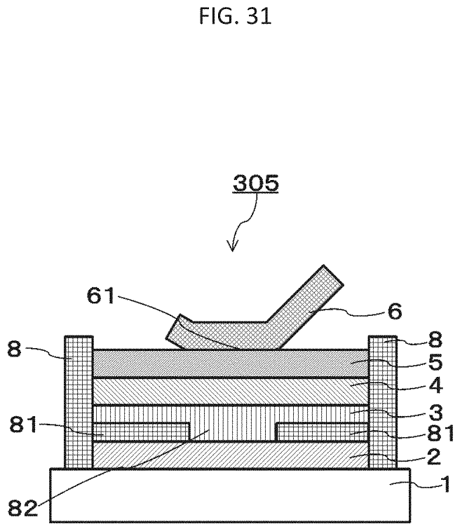

FIG. 31 is a schematic diagram of a cross-sectional structure showing another semiconductor device according to Embodiment 3.

In the figure, a semiconductor device 305 includes the semiconductor element 1, the first metal member 2, the second metal member 3, the third metal member 4, the fourth metal member 5, the bonding wire 6, which is the wiring member, with copper as the principal component, the insulation member 8, and the insulation member 81.

In FIG. 31, the outer edge of the semiconductor element 1 is disposed outside the outer edge of the first metal member 2. Although the semiconductor device 305 has the same metal member configuration as the semiconductor device 300 shown in FIG. 26, the semiconductor device 305 differs from the semiconductor device 300 in that the insulation member 8 is disposed such that the insulation member 8 is in contact with the sides of the first metal member 2, the second metal member 3, the third metal member 4, and the fourth metal member 5 in the peripheral area over the first main surface of the semiconductor element 1 and surrounds the first metal member 2, the second metal member 3, the third metal member 4, and the fourth metal member 5. The side of the insulation member 81 disposed in the peripheral area on the upper surface of the first metal member 2 is in contact with the insulation member 8 disposed around the metal members.

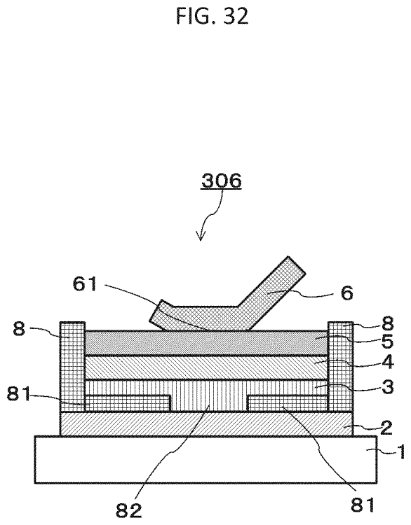

FIG. 32 is a schematic diagram of a cross-sectional structure showing another semiconductor device according to Embodiment 3.

In the figure, a semiconductor device 306 includes the semiconductor element 1, the first metal member 2, the second metal member 3, the third metal member 4, the fourth metal member 5, the bonding wire 6, which is the wiring member, with copper as the principal component, the insulation member 8, and the insulation member 81.

The semiconductor device 306 shown in FIG. 32 differs from the semiconductor device 305 shown in FIG. 31 in that the outer edge of the first metal member 2 of the semiconductor device is at the position of the outer edge of the insulation member 8 surrounding the first metal member 2 in FIG. 31.

In FIG. 31, the outer edge of the semiconductor element 1 is disposed outside the outer edge of the first metal member 2. The outer edge of the first metal member 2 is disposed outside the outer edges of the second metal member 3, the third metal member 4, and the fourth metal member 5. In the peripheral area on the upper surface of the first metal member 2, the insulation member 8 is disposed in contact with the sides of the second metal member 3, the third metal member 4, and the fourth metal member 5 to surround these metal members. The outer edge of the insulation member 8 is flush with the outer edge of the first metal member 2. The side of the insulation member 81 disposed in the peripheral area on the upper surface of the first metal member 2 is in contact with the insulation member 8 disposed around the metal members.

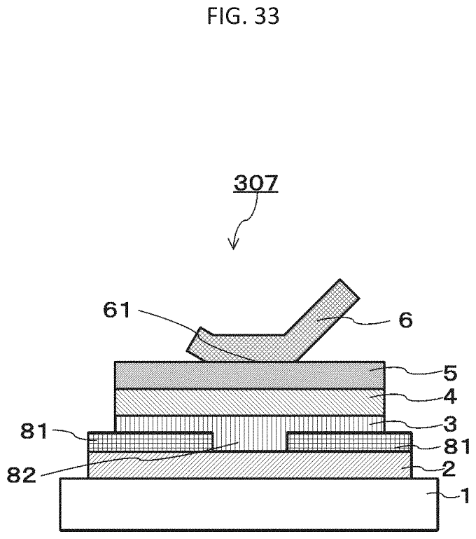

FIG. 33 is a schematic diagram of a cross-sectional structure showing another semiconductor device according to Embodiment 3.

In the figure, a semiconductor device 307 includes the semiconductor element 1, the first metal member 2, the second metal member 3, the third metal member 4, the fourth metal member 5, the bonding wire 6, which is the wiring member, with copper as the principal component, and the insulation member 81.

The semiconductor device 307 shown in FIG. 33 differs from the semiconductor device 306 shown in FIG. 32 in that the insulation member 8 that was disposed, as shown in FIG. 32, in contact with the sides of the second metal member 3, the third metal member 4, and the fourth metal member 5 of the semiconductor device to surround these metal members is currently removed. The sides of the second metal member 3, the third metal member 4, and the fourth metal member 5 are exposed because the insulation member 8 that was disposed in contact with the sides of the second metal member 3, the third metal member 4, and the fourth metal member 5 to surround these metal members is removed. The outer edge of the semiconductor element 1 is disposed outside the outer edge of the first metal member 2. The outer edge of the first metal member 2 is disposed outside the outer edges of the second metal member 3, the third metal member 4, and the fourth metal member 5. In the peripheral area of the first metal member 2, the insulation member 81 protrudes to expose its upper surface. The outer edge of the insulation member 81 is flush with the outer edge of the first metal member 2.

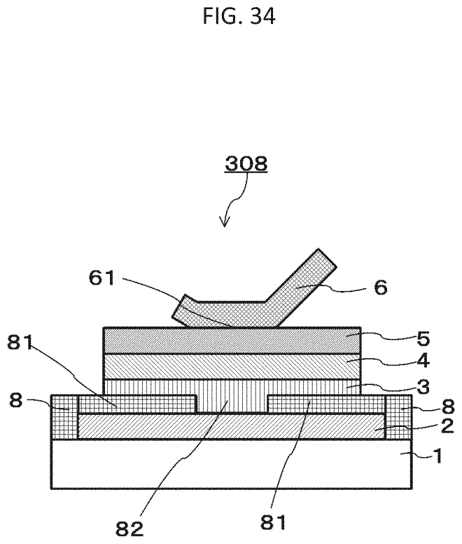

FIG. 34 is a schematic diagram of a cross-sectional structure showing another semiconductor device according to Embodiment 3.

In the figure, a semiconductor device 308 includes the semiconductor element 1, the first metal member 2, the second metal member 3, the third metal member 4, the fourth metal member 5, the bonding wire 6, which is the wiring member, with copper as the principal component, the insulation member 8, and the insulation member 81.

The semiconductor device 308 shown in FIG. 34 differs from the semiconductor device 307 shown in FIG. 33 in that the insulation member 8 is disposed in contact with the side of the first metal member 2 of the semiconductor device to surround the first metal member 2. In the peripheral area on the first main surface of the semiconductor element 1, the insulation member 81 covers the upper surface of the peripheral area of the first metal member 2 protruding outside the outer edge of the second metal member 3, and the insulation member 8 is in contact with the side of the first metal member 2. The outer edge of the semiconductor element 1 is disposed outside the outer edge of the first metal member 2. The outer edge of the first metal member 2 is disposed outside the outer edges of the second metal member 3, the third metal member 4, and the fourth metal member 5. The outer edge of the insulation member 8 is flush with the outer edge of the semiconductor element 1.

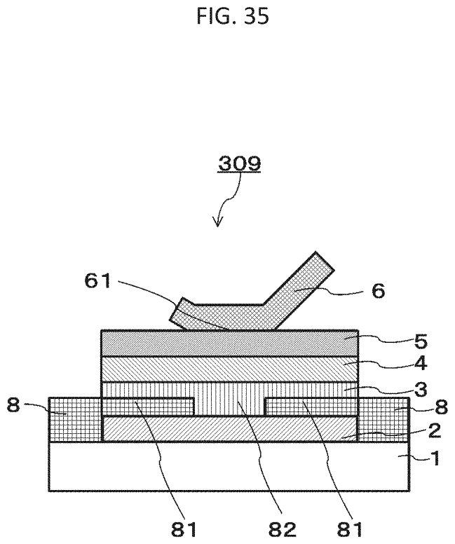

FIG. 35 is a schematic diagram of a cross-sectional structure showing another semiconductor device according to Embodiment 3.

In the figure, a semiconductor device 309 includes the semiconductor element 1, the first metal member 2, the second metal member 3, the third metal member 4, the fourth metal member 5, the bonding wire 6, which is the wiring member, with copper as the principal component, the insulation member 8, and the insulation member 81.

The semiconductor device 309 shown in FIG. 35 differs from the semiconductor device 308 shown in FIG. 34 in that the outer edge of the first metal member 2 is flush with the outer edges of the second metal member 3, the third metal member 4, and the fourth metal member 5. The insulation member 8 is disposed in the peripheral area on the first main surface of the semiconductor element 1. The outer edge of the semiconductor element 1 is disposed outside the outer edge of the first metal member 2. The outer edge of the first metal member 2 is flush with the outer edges of the second metal member 3, the third metal member 4, and the fourth metal member 5. The insulation member 81 is disposed in the peripheral area of the first metal member 2. The outer edge of the insulation member 81 is flush with the outer edge of the first metal member 2. The outer edge of the insulation member 8 is flush with the outer edge of the semiconductor element 1.

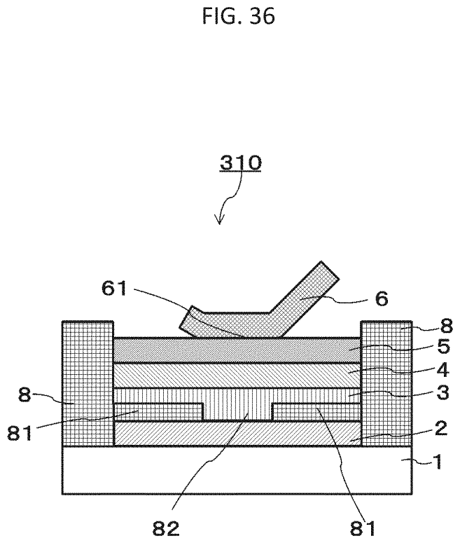

FIG. 36 is a schematic diagram of a cross-sectional structure showing another semiconductor device according to Embodiment 3.

In the figure, a semiconductor device 310 includes the semiconductor element 1, the first metal member 2, the second metal member 3, the third metal member 4, the fourth metal member 5, the bonding wire 6, which is the wiring member, with copper as the principal component, the insulation member 8, and the insulation member 81.

The semiconductor device 310 shown in FIG. 36 differs from the semiconductor device 309 shown in FIG. 34 in that the upper surface of the insulation member 8 is disposed above the upper surface of the fourth metal member 5. In the peripheral area on the first main surface of the semiconductor element 1, the insulation member 8 is disposed in contact with the sides of the first metal member 2, the second metal member 3, the third metal member 4, and the fourth metal member 5. The outer edge of the semiconductor element 1 is disposed outside the outer edge of the first metal member 2. The outer edge of the insulation member 8 is flush with the outer edge of the semiconductor element 1.

Next, the forming method of the insulation member 81 will be described.

One of the forming methods of the insulation member 81, for example, is to form the insulation member 81 by patterning itself. When using the resist material described in Embodiment 2 to form the insulation member 81, the same method as used when the fourth metal member 5 is patterned in Embodiment 2 can be used, in which the resist material, etc. is separately applied to the upper surface of the insulation member 81.

When directly patterning the insulation member 81 as done to the resist material, the insulation member 81 can be formed by referring to the process of Embodiment 2 in which the resist material is replaced with the material of the insulation member 81.

In the semiconductor device configured as described above, the second metal member 3 is formed on the upper surface of the first metal member 2, the third metal member 4 is formed on the upper surface of the second metal member 3, and the bonding wire 6 with copper as the principal component is provided on an upper surface of the fourth metal member 5 corresponding to the formation position of the third metal member 4, so that the impact of bonding of the bonding wire 6 on the underneath structure including the semiconductor element 1 can be reduced and the reliability of the semiconductor device can be improved.

Also, the insulation member 81 is disposed between the layers of the peripheral areas of the first metal member 2 and the second metal member 3, so that the stress generation can be suppressed compared to when the metal members are continuously stacked. Thus, by inserting the insulation member 8, the stress applied to the semiconductor element 1 can be reduced, which leads to reducing damage to the semiconductor element 1 caused by cracking and thus improving the reliability of the semiconductor device.

### Embodiment 4

Embodiment 4 differs from Embodiment 1, Embodiment 2, and Embodiment 3 in that the third metal member 4 is disposed only in the area corresponding to the bonding area 61 where the bonding wire 6 is bonded. Thus, the third metal member 4 is disposed only in the area corresponding to the bonding area 61 where the bonding wire 6 is bonded, so that the occurrence of cracking in the first metal member 2 due to the bonding wire 6 can be suppressed. Other respects are the same as in Embodiment 1, Embodiment 2, and Embodiment 3, so that the detailed descriptions will be omitted.

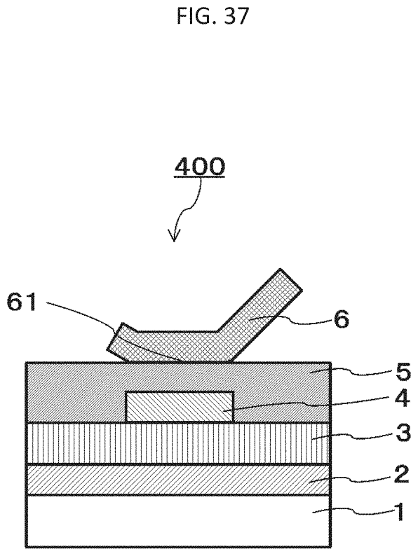

FIG. 37 is a schematic diagram of a cross-sectional structure showing a semiconductor device according to Embodiment 4.

In the figure, a semiconductor device 400 includes the semiconductor element 1, the first metal member 2, the second metal member 3, the third metal member 4, the fourth metal member 5, the bonding wire 6, which is the wiring member, with copper as the principal component, and the insulation member 8.

In the figure, the third metal member 4 is in contact with the upper surface of the third metal member 4 in its lower surface and is covered by the fourth metal member 5 in its side and upper surfaces. The bonding wire 6 is disposed on the upper surface of the fourth metal member 5 right over the third metal member 4 in accordance with the location where the third metal member 4 is disposed.

The third metal member 4 is disposed (inserted) as described above in order to prevent a crack from occurring in the metal members starting from the disposed position of the bonding wire 6 on the upper surface of the fourth metal member 5 where the bonding wire 6 is bonded and thus to prevent the semiconductor element 1 from being damaged by the crack that occurs. Therefore, the third metal member 4 should be provided at least directly under the area where the bonding wire 6 is disposed. For example, if Ni is used for the third metal member 4 and Cu is used for the second metal member 3 and the fourth metal member 5 in this configuration, Ni, which is formed on part of the second metal member 3, is surrounded by Cu and the proportion of Cu increases, accordingly. As a result, with a high thermal conductivity of Cu, which is higher than that of Ni, the heat dissipation from the semiconductor device 400 increases and thus the reliability of the semiconductor device 400 improves.

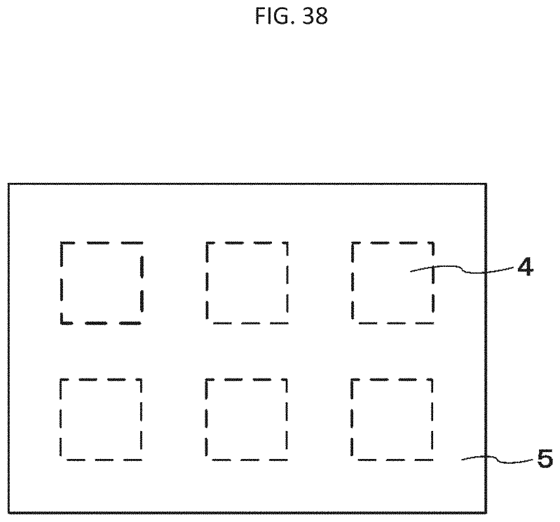

FIGS. 38 to 43 are each a schematic diagram of a planar structure showing the semiconductor device according to Embodiment 4. FIGS. 37 to 42 are each a plan view from above the upper surface of the fourth metal member 5, where the third metal member 4 is shown by the dashed line.

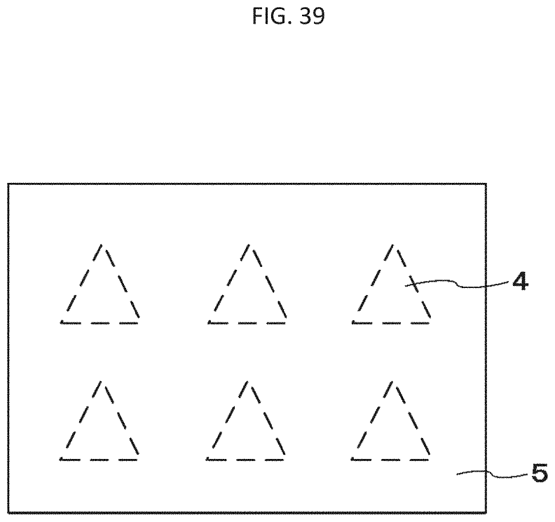

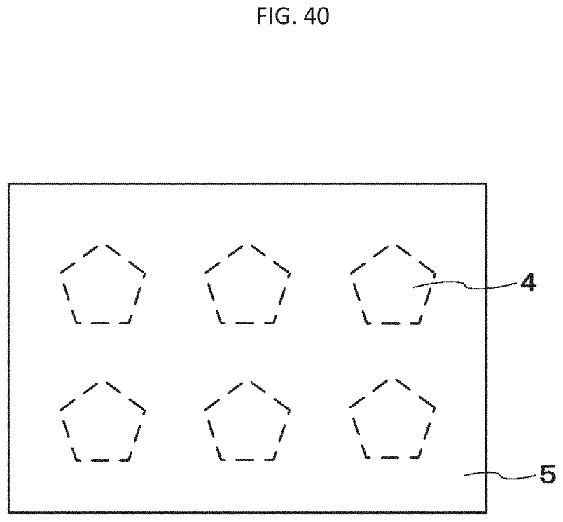

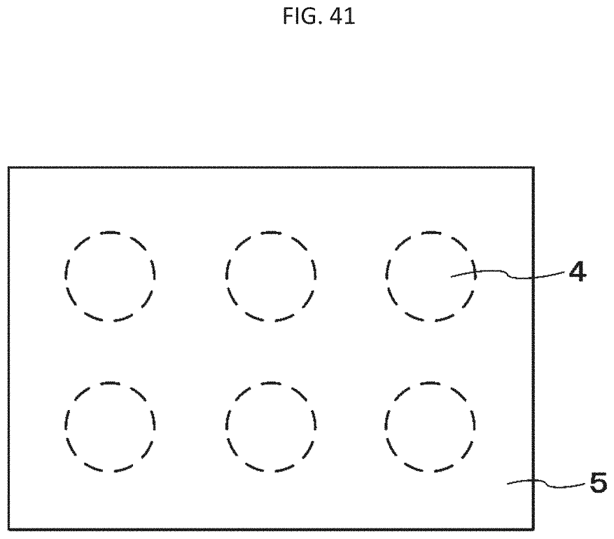

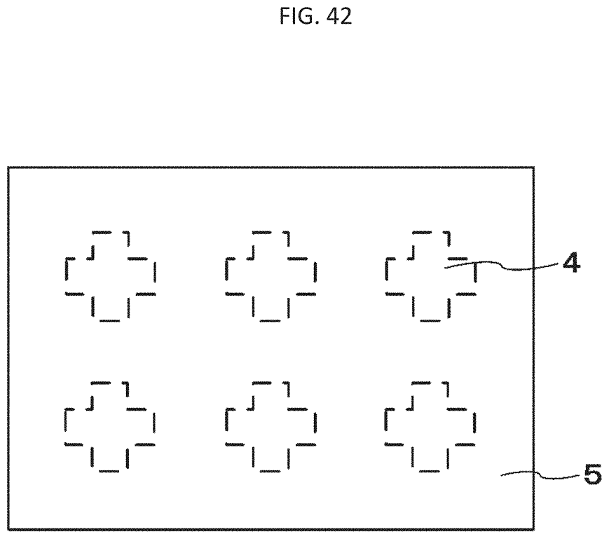

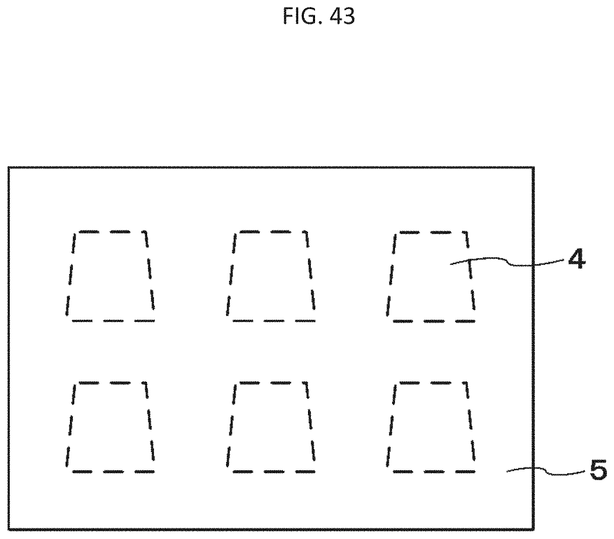

In FIG. 38, the shape of the third metal member 4 is rectangular (square). In FIG. 39, the shape of the third metal member 4 is triangular. In FIG. 40, the shape of the third metal member 4 is pentagonal. In FIG. 41, the shape of the third metal member 4 is circular. In FIG. 42, the shape of the third metal member 4 is cruciform. In FIG. 43, the shape of the third metal member 4 is trapezoidal. Thus, the planar shape of the third metal member 4 may be, for example, polygonal or donut-shaped such as circular, oval, square, rectangular, pentagonal, hexagonal, triangular, trapezoidal, cross-shaped, and star-shaped. The third metal member 4 with such a shape should be disposed directly under the area where the bonding wire 6 is disposed. The third metal member 4 should preferably be larger than the bonding area 61 where the bonding wire 6 is bonded. As shown in FIGS. 38 to 43, a plurality of third metal members 4 may be disposed in accordance with the number of the bonding wires 6 bonded to the upper surface of the fourth metal member 5 and their bonding areas 61.

In the semiconductor device configured as described above, the second metal member 3 is formed on the upper surface of the first metal member 2, the third metal member 4 is formed on the upper surface of the second metal member 3, and the bonding wire 6 with copper as the principal component is provided on an upper surface of the fourth metal member 5 corresponding to the formation position of the third metal member 4, so that the impact of bonding of the bonding wire 6 on the underneath structure including the semiconductor element 1 can be reduced and the reliability of the semiconductor device can be improved.

Because the third metal member 4 is disposed only in the area corresponding to the bonding area 61 where the bonding wire 6 is bonded, the occurrence of cracking in the first metal member 2 due to the bonding wire 6 can be suppressed.

### Embodiment 5

Here, a power converter to which the semiconductor device described in Embodiments 1 to 4 above is applied will be described. Application of this disclosure is not limited to a specific type of power converter. In Embodiment 5, however, an example in which this disclosure is applied to a three-phase inverter will be described.

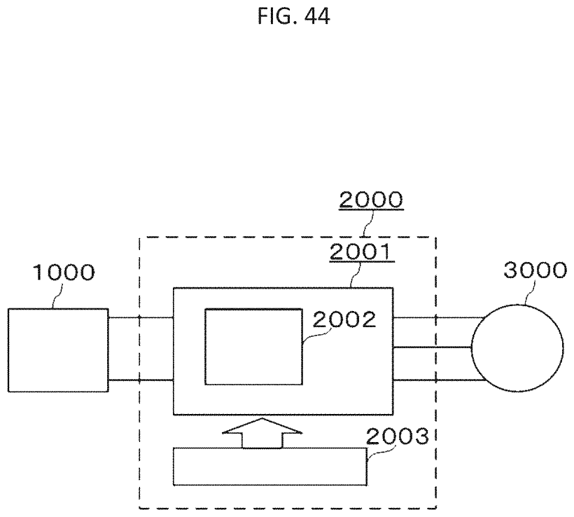

FIG. 44 is a block diagram showing a configuration of a power conversion system to which the power converter according to the present embodiment is applied.

The power conversion system, shown in FIG. 44, includes a power supply 1000, a power converter 2000, and a load 3000. The power supply 1000, which is a DC power supply, supplies DC power to the power converter 2000. For the power supply 1000, various devices and systems, such as a DC system, a solar cell, and a storage battery can be used. Also, a rectifier circuit and an AC/DC converter, connected to an AC system, can be used for the power supply. Furthermore, a DC/DC converter that converts DC power outputted from the DC system to a predetermined power may be used for the power supply 1000.

The power converter 2000, which is a three-phase inverter connected between the power supply 1000 and the load 3000, converts the DC power supplied from the power supply 1000 to AC power, and supplies the AC power to the load 3000. As shown in FIG. 44, the power converter 2000 includes a main conversion circuit 2001, which converts DC power to AC power and outputs it, and a control circuit 2003, which outputs a control signal for controlling the main conversion circuit 2001 to the main conversion circuit 2001.

The load 3000 is a three-phase electric motor driven by the AC power supplied from the power converter 2000. Note that the load 3000 is an electric motor installed in various electrical equipment, not being limited to any specific application. For example, it is an electric motor used in a hybrid car, an electric car, a railroad car, an elevator, and air conditioning equipment.

The following is a detailed description of the power converter 2000. The main conversion circuit 2001 includes a switching device and a freewheeling diode (both not shown). The main conversion circuit 2001 converts the DC power supplied from the power supply 1000 to AC power by the switching operation of the switching device and supplies the AC power to the load 3000. The specific circuit configurations of the main conversion circuit 2001 are various. The main conversion circuit 2001 according to the present embodiment is a three-phase full-bridge circuit with two levels and includes six switching devices and six freewheeling diodes each connected in reverse parallel to one of the switching devices.

At least one of the switching devices and the freewheeling diodes included in the main conversion circuit 2001 is the switching device or the freewheeling diode included in the semiconductor device 2002 corresponding to the semiconductor device according to at least one of Embodiments 1 to 4 described above. The six switching devices are combined into pairs. In each pair, the switching devices are connected in series to form a pair of upper and lower arms. Each pair of the upper and lower arms constitutes a phase (U-phase, V-phase, or W-phase) of the full bridge circuit. The output terminals of the pairs of the upper and lower arms, in other words, the three output terminals of the main conversion circuit 2001, are connected to the load 3000.

The main conversion circuit 2001 includes a drive circuit (not shown) to drive the switching devices. The drive circuit may be built in the semiconductor device 2002 or may be separately provided. The drive circuit generates a drive signal to drive the switching devices of the main conversion circuit 2001 and supplies it to the control electrodes of the switching devices of the main conversion circuit 2001. Specifically, the drive circuit outputs a drive signal to turn on a switching device and a drive signal to turn off a switching device to their control electrodes in accordance with the control signal from the control circuit 2003 to be described later. The drive signal to keep a switching device in an ON state is a voltage signal (ON signal) above the threshold voltage of the switching device. The drive signal to keep the switching device in an OFF state is a voltage signal (OFF signal) below the threshold voltage of the switching device.

The control circuit 2003 controls the switching devices of the main conversion circuit 2001 so that the load 3000 is supplied with the power it needs. Specifically, the control circuit 2003 calculates the time (ON time) during which each of the switching devices of the main conversion circuit 2001 should be in an ON state on the basis of the power to be supplied to the load 3000. For example, PWM control, in which ON time of each switching device is modulated in accordance with the voltage to be outputted, can be applied to the control of the main conversion circuit 2001. A control command (control signal) is outputted to the drive circuit of the main conversion circuit 2001 in a timely manner so that an ON signal is outputted to the switching device that should be in an ON state and an OFF signal is outputted to the switching device that should be in an OFF state. The drive circuit outputs the ON signal or the OFF signal to the control electrode of each of the switching devices as a drive signal in accordance with this control signal.

The power converter 2000 according to the present embodiment uses the semiconductor device according to Embodiments 1 to 4 as the semiconductor device 2002 constituting the main conversion circuit 2001. This makes it possible to bond, as the bonding wire 6, a copper wire or the like on the bonding area 61 more firmly and in a better condition. This improves the reliability of the power converter 2000.

In the present embodiment, an example is described, in which this disclosure is applied to a three-phase inverter with two levels. However, this disclosure is not limited as such and can be applied to various power converters. In the present embodiment, a power converter with two levels is used for description. However, this disclosure can also be applied to a multi-level power converter with three or more levels and even to a single-phase inverter if the load is single-phased. This disclosure can also be applied to a DC/DC converter, an AC/DC converter, and the like when supplying power to a DC load or the like.

Not limited to application to an electric motor as the load as described above, the power converter according to this disclosure can be used, for example, as a power supply system of an electric discharge machine, a laser processing machine, an induction heating cooker, and a non-contact power supply, and also as a power conditioner of a photovoltaic power generation system and a power storage system.

The configurations of the semiconductor device described in each embodiment may be combined in various ways as necessary.

The embodiments disclosed herein are illustrative, not restrictive. The scope of this disclosure is indicated by the scope of the claims, not by the scope of the descriptions provided above, and includes all modifications made within the meaning and scope equivalent to those of the claims.

### DESCRIPTION OF SYMBOLS

1 semiconductor element,
2 first metal member,
3 second metal member,
4 third metal member,
fourth metal member,
6 wiring member,
7 resist material,
8,81 insulation member,
61 bonding area,
82 opening,
100, 101, 103, 200, 201, 202, 210, 211, 212, 300, 301, 302, 303, 304, 305, 306, 307, 308, 309, 310, 400, 2002 semiconductor device,
1000 power supply,
2000 power converter,
2001 main conversion circuit,
2003 control circuit,
3000 load

1.-13. (canceled)

14. A semiconductor device comprising:
a semiconductor element with a first main surface;
a first metal member formed on the first main surface;
a second metal member formed on an upper surface of the first metal member;
a third metal member formed on an upper surface of the second metal member;
a fourth metal member with copper as a principal component, formed on an upper surface of the third metal member; and
a wiring member with copper as a principal component, bonded to an upper surface of the fourth metal member corresponding to a formation position of the third metal member, wherein a material of the first metal member is aluminum and a material of the second metal member is copper.

15. The semiconductor device according to claim 14, wherein a material of the third metal member is nickel.

16. The semiconductor device comprising:
a semiconductor element with a first main surface;
a first metal member formed on the first main surface;
a second metal member formed on an upper surface of the first metal member;
a third metal member formed on an upper surface of the second metal member;
a fourth metal member with copper as a principal component, formed on an upper surface of the third metal member;
a wiring member with copper as a principal component, bonded to an upper surface of the fourth metal member corresponding to a formation position of the third metal member; and
an insulation member having an opening at a position corresponding to a bonding area of the wiring member and the fourth metal member, disposed in at least one of regions between the first metal member, the second metal member, the third metal member, and the fourth metal member.

17. The semiconductor device according to claim 14, wherein a hardness of a material of either the second metal member or the third metal member is equal to or higher than a hardness of a material of the fourth metal member.

18. The semiconductor device according to claim 16, wherein a hardness of a material of either the second metal member or the third metal member is equal to or higher than a hardness of a material of the fourth metal member.

19. The semiconductor device according to claim 14, wherein a hardness of the material of the second metal member is equal to or lower than a hardness of the material of the third metal member.

20. The semiconductor device according to claim 16, wherein a hardness of the material of the second metal member is equal to or lower than a hardness of the material of the third metal member.

21. The semiconductor device according to claim 14, wherein a hardness of the material of the first metal member is equal to or lower than a hardness of the material of the second metal member and a hardness of the material of the third metal member.

22. The semiconductor device according to claim 16, wherein a hardness of the material of the first metal member is equal to or lower than a hardness of the material of the second metal member and a hardness of the material of the third metal member.

23. The semiconductor device according to claim 14, wherein an outer edge of the fourth metal member is disposed inside an outer edge of at least one of the first metal member, the second metal member, and the third metal member which are formed under the fourth metal member.

24. The semiconductor device according to claim 16, wherein an outer edge of the fourth metal member is disposed inside an outer edge of at least one of the first metal member, the second metal member, and the third metal member which are formed under the fourth metal member.

25. The semiconductor device according to claim 23, wherein lengths of the second metal member, the third metal member, and/or the fourth metal member which are disposed above the insulation member are each from 10 μm to 100 μm.

26. The semiconductor device according to claim 16, wherein a material of the first metal member is aluminum, a material of the second metal member is copper, and a material of the third metal member is nickel.

27. The semiconductor device according to claim 14, wherein the third metal member is formed on part of the second metal member.

28. The semiconductor device according to claim 27, wherein the shape of the third metal member is circular or polygonal.

29. The semiconductor device according to claim 14, wherein a thickness of the third metal member is from 1 μm to 50 μm.

30. A power converter comprising:
a main conversion circuit including a semiconductor device according to claim 14, to convert inputted power and output the converted power; and
a control circuit to output a control signal for controlling the main conversion circuit to the main conversion circuit.

31. A manufacturing method of a semiconductor device, comprising:
preparing a semiconductor element with a first main surface;
forming a first metal member on the first main surface;
forming a second metal member on an upper surface of the first metal member;
forming a third metal member on an upper surface of the second metal member;
forming a fourth metal member with copper as a principal component on an upper surface of the third metal member;
bonding a wiring member with copper as a principal component to an upper surface of the fourth metal member corresponding to a formation position of the third metal member; and
forming an insulation member having an opening at a position corresponding to a bonding area of the wiring member and the fourth metal member, disposed in at least one of regions between the first metal member, the second metal member, the third metal member, and the fourth metal member.

32. The manufacturing method of a semiconductor device according to claim 31, wherein a material of the first metal member is aluminum and a material of the second metal member is copper.

33. The manufacturing method of a semiconductor device according to claim 31, wherein a material of the third metal member is nickel.
